(19) United States
(12) Patent Application Publication
(10) Pub. No.: US 2020/0334397 A1
(43) Pub. Date: Oct. 22, 2020

(54) SYSTEM AND METHOD FOR 2D TO 3D MODEL CREATION FOR A MEMS DEVICE

(71) Applicant: Coventor, Inc., Cary, NC (US)

(72) Inventors: Arnaud Krust, Palaiseau (FR); Arnaud Parent, Bullion (FR); Alexandre Sinding, Paris (FR)

(21) Appl. No.: 16/917,684

(22) Filed: Jun. 30, 2020

Related U.S. Application Data
(63) Continuation-in-part of application No. PCT/US2019/015565, filed on Jan. 29, 2019.
(60) Provisional application No. 62/624,703, filed on Jan. 31, 2018.

(51) Int. Cl. G06F 30/17; G06F 30/23; G06F 30/12

(52) U.S. Cl. CPC G06F 30/17; G06F 30/12; G06F 30/23

(57) ABSTRACT

Systems and methods for creating 3D MEMS device models from a 2D polygonal description are described. Embodiments enable the identification of corresponding 3D model components from a library of parameterized MEMS model components using 2D polygonal descriptions of a MEMS device. Embodiments further enable the inclusion of meshed components into created MEMS device models.

### RELATED APPLICATION

This application is a continuation-in-part application claiming priority to PCT application No. PCT/US2019/015565, entitled “System and Method for 2D to 3D Compact Model Creation For a MEMS Device”, filed Jan. 29, 2019, which claims the benefit of, and priority to, U.S. Provisional Patent Application No. 62/624,703, filed Jan. 31, 2018, the contents of both applications incorporated by reference herein in their entirety.

### BACKGROUND

Computer Aided Design (CAD) and Computer Aided Engineering (CAE) tools are used, respectively, to design and simulate virtual models of mechanical devices prior to producing actual physical devices. Similarly, Electronic Design Automation (EDA) tools are used to design and simulate virtual models of electrical and electronic devices prior to producing actual physical devices. CAD, CAE, and EDA tools are interactive software programs that run on a digital computer with a graphical display device. Attributes of CAD/CAE tools and EDA tools must be combined to design and simulate virtual models of multi-physics devices such as Micro Electro-Mechanical Systems (MEMS) devices prior to beginning the costly and time-consuming process of fabricating the actual physical devices.

MEMS are micro-scale or nano-scale devices, typically fabricated in a similar fashion as integrated circuits (ICs), to exploit the miniaturization, integration, and batch processing attainable with semiconductor manufacturing processes. Unlike ICs which consist solely of electrical components, MEMS devices combine components from multiple physical domains and may contain, for example, electrical, mechanical, magnetic, radio frequency (RF), optical and fluidic components. MEMS devices appear in many forms and may include micro-electromechanical sensors and actuators such as gyroscopes, accelerometers, and pressure sensors, micro-fluidic devices such as ink jet heads, Radio-Frequency (RF) devices such as switches, resonators, varactors, and passives, and optical devices such as micro-mirrors and fiber alignment devices. Typically, MEMS devices are not useful by themselves. To provide a useful function, a MEMS device must be incorporated in a system that includes electronic circuits that either control the MEMS devices or process electrical output signals from the MEMS devices. Most MEMS devices are comprised of a MEMS sensing or actuation element, i.e. the MEMS device itself, and accompanying electronics, i.e. an IC, that processes the output signal from the MEMS device and/or controls the MEMS device.

A 3D multi-physics design environment (hereafter “3D design environment”) enables the design and simulation of multi-physics devices such as MEMS devices. An exemplary 3D design environment is described in U.S. Pat. No. 9,015,016 entitled “System and Method for Three-Dimensional Schematic Capture and Result Visualization of Multi-Physics System models”, the contents of which are incorporated herein by reference in their entirety. The 3D design environment may be programmatically integrated with a system modeling environment that is suitable for system-level design and simulation of analog-signal ICs, mixed-signal ICs and multi-physics systems. A parameterized MEMS device model may be created in a 3D graphical view in the 3D design environment using parameterized model components. The parameterized model components may each be associated with an underlying behavioral model and may be selected from a multi-physics/MEMS component library. After the MEMS device model is completed, it may be exported to a system modeling environment. The MEMS device model may be exported to the system modeling environment without subjecting the model to preliminary finite element meshing.

The exported MEMS device model allows circuit simulations involving the MEMS device and associated electronic circuitry to be conducted in the system modeling environment. Circuit simulation results may be transferred back into the 3D design environment in order to be visualized using the 3D view generators of the 3D design environment. The 3D view may display an animation of the mechanical motion of the MEMS device. The user may then export a parameterized layout cell to a layout editor that can be used to directly generate a layout of the MEMS device.

Conventionally, two approaches have existed for modeling a MEMS device. A first approach is to mesh the entire 3D geometry and then run a finite element method. In a second approach, the model can be an assembly of building blocks with underlying high order behavioral models e.g. suspensions, electrostatic combs and perforated plates. Dedicated meshing approaches can supplement the behavioral models if high mechanical accuracy is required. Each individual model is specialized to represent accurately a functionality with the least possible degrees of freedom. Such an assembly constitutes a model that is often smaller (in terms of number of degrees of freedom and equations to solve) and faster to simulate than the conventional finite element method with little or no loss in accuracy. The model is thus sometimes called a “compact model”. In this second approach, the 3D design environment has a library of components available for building a compact model. This library is customizable and components can be added/removed from a list. The components can also be preconfigured.

One workflow in the MEMS industry is to build a 3D model out of a 2D polygonal description (e.g. a description in a GDSII format). This polygonal description contains several layers of 2D polygons. For example, the different layers can represent different materials or fabrication steps. The layers can also be used as information layers, giving a sense of the purpose of a part of the device. The geometries sharing a functionality are frequently grouped on the same layer so that each layer represents one functionality.

### BRIEF SUMMARY

Embodiments of the present invention enable the creation of a 3D model of a MEMS device from a 2D polygonal description of the device using an assembly of heterogeneous components extracted from a library of components in a 3D design environment. Components in the library of components may be customized to interpret 2D polygons as their 3D component equivalent. Since for a given functionality, there are only a few components available (e.g. for addressing different geometries), components in the component library are preconfigured by a user and the layer on which a particular functionality is expected is specified. A geometric criterion is used to distinguish between differently shaped components appearing on the same layer in the 2D polygonal description that share a given functionality. In some embodiments, a 3D compact model may be created by assembling the hetererogenous components. In other embodiments, the 3D model being created may be a hybrid model that also includes at least one meshed component.

In one embodiment, a computing device-implemented method of creating 3D MEMS device models from 2D polygonal descriptions in a 3D design environment includes the step of providing a parameterized component library holding components for the 3D design environment. Each component has a geometric shape. The method further includes receiving in the 3D design environment a user configuration of each component. The user configuration specifies a layer of a 2D polygonal description on which the component is expected to appear. The method additionally imports a 2D polygonal description of a MEMS device model into the 3D design environment. The 2D polygonal description includes multiple geometric shapes and multiple layers and separates model functionality by layer. The method also identifies in the 3D design environment each geometric shape on each layer of the imported 2D polygonal description and identifies a corresponding component for geometric shapes identified on a layer. Additionally, the method assembles in the 3D design environment multiple heterogeneous components into a 3D MEMS device model using multiple corresponding components.

In another embodiment, a system for creating 3D MEMS device models from 2D polygonal descriptions in a 3D design environment includes at least one computing device equipped with a processor that is configured to generate a 3D design environment for MEMS device models. The 3D design environment is configured to provide a parameterized component library holding multiple components, each component having a geometric shape. The 3D design environment is also configured to receive a user configuration of each component that specifies a layer of a 2D polygonal description on which the component is expected to appear and to import a 2D polygonal description of a MEMS device model. The 2D polygonal description includes multiple geometric shapes and multiple layers and separates model functionality by layer. Further, the 3D design environment is configured to identify each geometric shape on each layer of the imported 2D polygonal description. The 3D design environment is also configured to identify a corresponding component in the parameterized component library for geometric shapes identified on a layer. Additionally, the 3D design environment is configured to assemble multiple heterogeneous components into a 3D MEMS device model using multiple corresponding components. The system also includes a display surface in communication with the computing device. The display surface is configured to display the 3D compact MEMS device model in a 3D view.

### BRIEF DESCRIPTION OF THE DRAWINGS

The accompanying drawings, which are incorporated in and constitute a part of this specification, illustrate one or more embodiments of the invention and, together with the description, help to explain the invention. In the drawings:

FIG. 1 depicts an exemplary 3D design environment usable by an embodiment of the present invention;

FIG. 2A depicts an empty 3D view generated by a schematic editor of the 3D design environment prior to the MEMS device assembly;

FIG. 2B depicts parameterization of an exemplary component selected from a component library using global variables inside the 3D schematic editor;

FIG. 3 depicts parameterization of another exemplary component selected from a component library using global variables inside the 3D schematic editor and the 3D view of the selected exemplary part;

FIG. 4 depicts an exemplary completed MEMS device model displayed in the 3D schematic editor and a listing of global variables used for component parameterization;

FIG. 5A depicts another exemplary completed MEMS device model displayed in the 3D view generated by the 3D schematic editor and a listing of global variables used for component parameterization;

FIG. 5B illustrates mechanical connectors of the exemplary MEMS device model illustrated in FIG. 5A;

FIG. 5C illustrates electrical connectors of the exemplary MEMS device model illustrated in FIG. 5A;

FIG. 6A depicts a first editor, a material property editor;

FIG. 6B depicts a second editor, a process editor;

FIG. 7 depicts the 3D design environment exporting a symbol of an exemplary MEMS device model together with the underlying behavioral model into a system modeling environment;

FIG. 8 depicts a symbol representative of the created MEMS device model being added to a schematic in a system modeling environment;

FIG. 9 depicts global variables used in the MEMS device model that are accessible as symbol parameters in the schematic editor of a system modeling environment;

FIG. 10 depicts the transfer of the simulation results from a system modeling environment into the 3D design environment and the animation of the results in the 3D view;

FIG. 11 illustrates an overview of the design process including the 3D design environment and the system modeling environment;

FIG. 12 is a flowchart of an exemplary sequence of steps followed by an embodiment of the present invention to create a 3D compact model from a 2D polygonal description in a 3D design environment;

FIG. 13 depicts similarly shaped components in the 3D design environment in an embodiment;

FIG. 14 depicts an exemplary process editor UI in an embodiment;

FIG. 15 depicts an exemplary UI for the component library in an embodiment;

FIGS. 16A-16B depict an exemplary model creation in an embodiment;

FIG. 17 depicts an exemplary electrostatic comb in an embodiment;

FIG. 18 depicts an exemplary process editor UI in an embodiment;

FIG. 19 depicts an exemplary UI for the component library;

FIG. 20A depicts an exemplary layout in an embodiment;

FIG. 20B depicts an exemplary model generated from the layout of FIG. 20A;

FIG. 21A depicts an exemplary output from hexahedral meshing in an embodiment;

FIG. 21B depicts another exemplary output from hexahedral meshing in an embodiment;

FIG. 22 depicts a graphical user interface provided by the 3D design environment configured to accept hexahedral meshing parameters for a plate in an exemplary embodiment;

FIG. 23A depicts an exemplary graphical user interface for specifying a mechanical connector location in an exemplary embodiment;

FIG. 23B depicts a view of a large rigid face;

FIG. 23C depicts a view of a small rigid face in an exemplary embodiment;

FIG. 23D depicts a suspension connected to a plate component in an exemplary embodiment;

FIG. 24 depicts an exemplary graphical user interface provided by the 3D design environment enabling a user to specify a maximum number of degrees of freedom in a simulation using a meshed component;

FIG. 25 depicts a graphical user interface provided by the 3D design environment configured to accept hexahedral meshing parameters for a beam in an exemplary embodiment;

FIG. 26 depicts a view of differences between an orthogonal mesh and an extruded mesh in an exemplary embodiment;

FIG. 27 depicts a view of the effect of sidewall angle in an orthogonal mesh and an extruded mesh in an exemplary embodiment;

FIG. 28 depicts a view of meshing with merged geometry in an exemplary embodiment;

FIGS. 29A-29B depict graphical user interfaces for user selection of parameters for running a convergence study in an exemplary embodiment.

### DETAILED DESCRIPTION

Different techniques have been attempted to model MEMS devices. One existing method for building a 3D model of a MEMS device from a 2D polygonal description takes as input a 2D description of the geometry (a layout) and a description of the fabrication process steps to build an idealized 3D model. This 3D model is then meshed for simulation. This process is inappropriate for assembling compact models as it cannot identify different components in the structure.

Another existing method for building a 3D model of a device from a 2D polygonal description creates a rigid 3D model from a 2D description. The 2D polygons are read and then extruded to get a 3D model. As the software has no other information, only one type of component from the library can be created this way. Therefore this process cannot create a proper compact model as it cannot identify different components (different functional parts with specific behavior and models). For example, this approach cannot create electrostatic components (i.e. components that model the electrostatic field between conductors that are represented by distinct polygons in the 2D source).

An additional existing method for producing a compact model from a 2D source utilizes additional information stored in the 2D description. For example, to define an electrostatic comb, the different parameters (pitch, finger length, width, gap . . . ) are stored as an open polyline in a separate layer. The first segment length is interpreted as the pitch, the second as the finger length, etc. This information is read and interpreted by a script that translates it into the creation of different types of components. However, this ad hoc approach cannot be easily modified to handle different user needs. For example, it would be difficult to implement this approach for a large number of different components. Also, this approach requires extensive modifications to the original 2D representation, such as adding polylines that encode parameters, that are not directly the geometry that is to be imported. In a layout editor, users can copy/paste and perform Boolean operations on the geometries, but they cannot automatically create such polylines. Accordingly, this approach shifts the complexity of the MEMS device modeling problem to the creation of these polylines. Furthermore, the open polylines are not part of the GDSII format (the standard source for 2D design descriptions) and are proprietary to specific tools.

To avoid these problems with conventional approaches, embodiments of the present invention take advantage of the customizability of a library of parameterized MEMS components provided in a 3D design environment to help assemble a compact model of heterogeneous components from the information contained in a 2D polygonal description of a MEMS device. More particularly, embodiments enable the customization of the components in the library of components in a 3D design environment so as to cause the interpretation of the 2D polygons as their 3D component equivalent. Since for a given functionality, there are only a few components available (e.g. for addressing different geometries) a user preconfigures components in the component library and specifies on which layer(s) (of a 2D polygonal description) this functionality is expected. A geometric criterion is used to distinguish between different types of components sharing a given functionality that appear on the same layer. Once the corresponding components have been identified, they are assembled into a 3D MEMS device compact model.

In another embodiment, this approach to creating a compact model is supplemented by further identifying one or more additional components to undergo hexahedral meshing. The user is then able to connect the meshed elements to other components in the created MEMS device via face connectors. The inclusion of the meshed components in the created MEMS device enables the 3D design environment to run accurate mechanical simulations on complex devices.

Prior to discussing the compact and hybrid model generation techniques provided by embodiments, an exemplary 3D design environment for MEMS design which may be adapted to practice the embodiments is first described.

### Exemplary 3D Design Environment

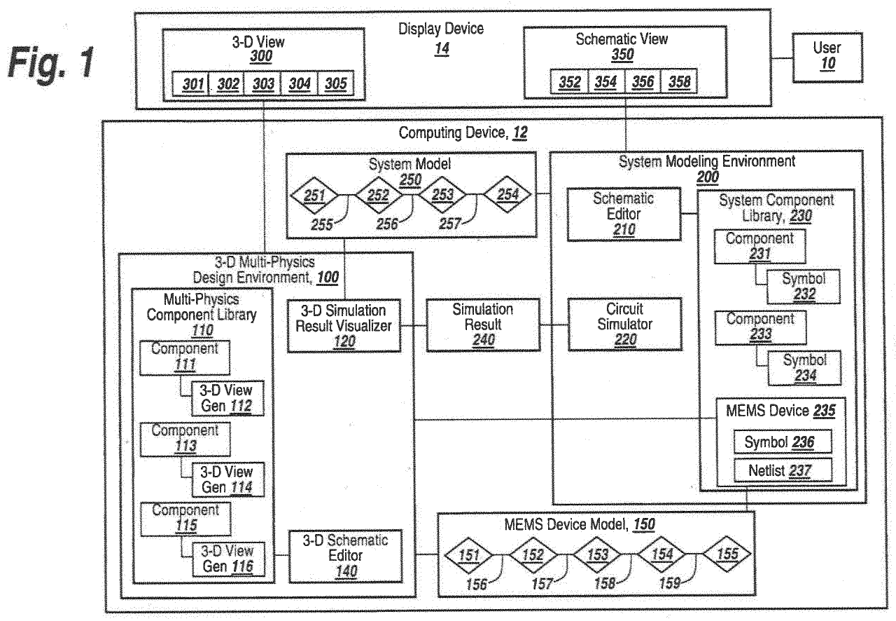

An exemplary 3D design environment suitable for practicing embodiments of the present invention will now be discussed with reference to FIGS. 1-11. It should be appreciated that the description of the 3D design environment is made for purposes of illustration and explanation and embodiments of the present invention are not limited to the described environment. For example although the following exemplary 3D design environment description discusses the ability of a user to manually assemble a model from library components in the 3D view, the environment also supports the embodiments of the present invention discussed herein which enable the programmatic generation of a MEMS device model from an imported 2D polygonal description.

A multi-physics device model, such as a MEMS device model, may be created in a three-dimensional (3D) design environment that is integrated with a system modeling environment. The created device model includes an underlying behavioral model associated with each component of the created device model. The created device model may be exported to a system modeling environment where it can be integrated into a schematic design and used in performing a circuit simulation or co-simulation. The behavioral model for the created device may be parameterized with respect to manufacturing and design dependent variables such as material properties and dimensional variations, as well as geometric properties of the design. The results of system-level simulations or co-simulations performed in the system modeling environment can subsequently be loaded back into the 3D design environment for result visualization and animation. A user viewing the displayed results in the 3D design environment may indicate satisfaction with the results and a parameterized 2-D layout cell may be programmatically generated and sent to a 2-D layout editor in the system modeling environment.

The created MEMS device model, which may be used for system modeling, is automatically created by the 3D design environment from the behavioral models of the individual MEMS components. The MEMS device model may be automatically transferred to the system modeling environment for simulation without requiring the model to first undergo FEM. This process of creating a 3D schematic by assembling components in a 3D view is called “three-dimensional schematic capture”. The exported MEMS device model allows for circuit simulations involving both the created MEMS device and the associated electronic circuitry in the system modeling environment. The 3D design environment can be used in an integrated fashion with system modeling environments.

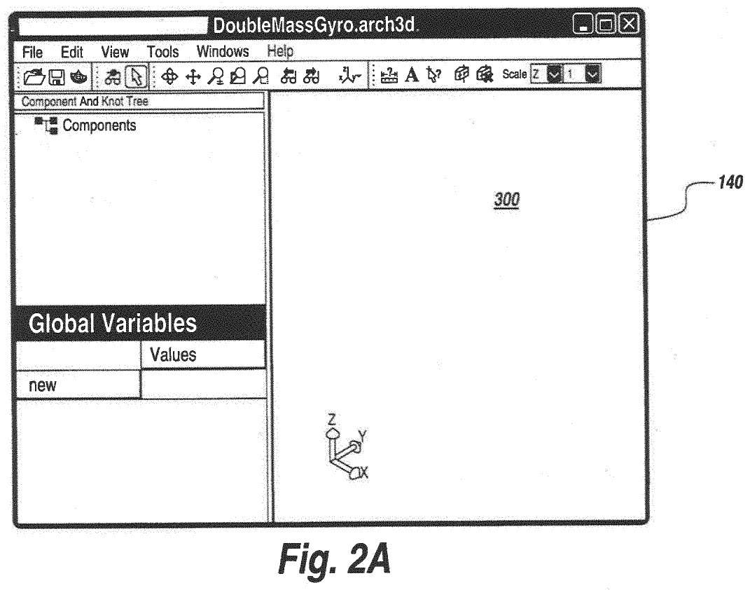

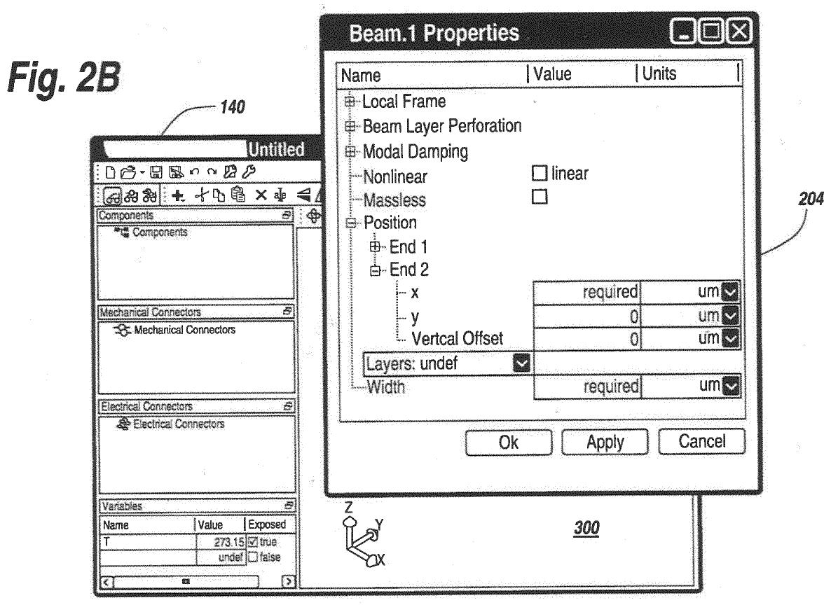

FIG. 1 depicts an exemplary 3D design environment usable by an embodiment of the present invention. FIGS. 2A-11 describe various interactions between the components illustrated in FIG. 1. FIG. 1 is referenced throughout the detailed description.

A computing device 12 providing a 3D multi-physics design environment 100 (“3D design environment”) and a schematic-based system modeling environment 200 is illustrated in FIG. 1. The computing device 12 may be a server, workstation, laptop, or some other type of electronic device equipped with a processor and capable of executing instructions to provide the 3D design environment 100 and the system modeling environment 200. The 3D design environment 100 may include a MEMS component library 110, a 3D simulation result visualizer 120, and a 3D schematic editor 140. It will be appreciated that the individual components depicted in FIG. 1 may appear in combination or in different configurations from those depicted in FIG. 1 without departing from the scope of the present invention.

The 3D schematic editor 140 is used to create and/or edit a 3D MEMS device model 150. The user 10 assembles a MEMS device model 150 in the 3D design environment 100 by selecting one or more instances of MEMS components 111, 113 and 115 from the MEMS component library 110 and configures the component parameters. As discussed further herein, in some embodiments, the component library may be customized in order to associate a layer of a 2D description with some components. Component parameters can be entered in the form of numbers or as an algebraic expression that references one or more global variables. All global variables used to parameterize the MEMS device 150 may be stored and defined in the 3D design environment 100.

The library components 111, 113 and 115 may represent entities from different physical domains, such as masses, plates, magnets, lasers, optical lenses, electrostatic comb structures and electrodes. The component parameters may include geometrical dimensions such as position, orientation, length, width and height, layer names or material properties like density and modulus of elasticity. Component parameters may be entered in the form of numbers or as an expression of one or more global variables. An alternative approach for defining geometrical component parameters receives point selections or freeform drawing on a 2-D or 3D canvas.

Each model component in the MEMS component library 110 may include a mathematical behavioral model represented by components 111, 113 and 115, and a corresponding 3D view generator 112, 114 and 116 that is a computer script or program containing the information needed to draw a 3D graphical view of each component. The underlying behavioral models of each component describe how the individual components behave mathematically when subjected to electrical or mechanical stimuli or stimuli from other domains. 3D view generators 112, 114 and 116 use the parameter information (optionally together with other design information like the fabrication process description) to create a 3D image 301, 302, 303, 304 and 305 of the components 151, 152, 153, 154 and 155 after the user 10 successfully completes the parameter input.

The underlying behavioral models are distinct from finite element models in that they use whatever mathematical (analytical) or numerical formulation is most efficient for representing the physical behavior of the modeled entity as opposed to generic shape functions that have a polynomial or other standard basis as is the case with finite elements. A suspension of a typical MEMS device, for instance, can typically be modeled as a collection of mechanical beam segments. Other components that can be assembled to model MEMS devices may include rigid and flexible mechanical plates of various shapes (rectangular, triangular, arc segments, etc.), inter-digitated electrostatic comb drives of various shapes and configurations, and flat or curved electrodes that may be placed above, below or to the side of any of the above mentioned mechanical elements. Each of these components must have an associated behavioral model that efficiently represents its physical behavior. The behavioral model for a mechanical beam may be an analytical solution of a well-known beam theory, such as the Euler-Bernoulli beam equation. Such a mathematical solution may be expressed explicitly in terms of the geometric parameters of the beam such as its length, width and thickness, and material properties such as Young's modulus. In addition, the behavioral model may have mechanical connection points such as the ends of a beam that specify where and how it can be connected to other mechanical components. The behavior of a rigid plate segment may be modeled by the equations governing rigid body dynamics, which depend on its inertial coefficients, which can in turn be expressed explicitly in terms of its geometric parameters and density. The behavioral models for electrostatic forces between electrodes and mechanical elements may be modeled by the simple equations for electrostatic force between flat plates of equivalent size, or by more sophisticated means such as conformal mapping in the case of inter-digitated comb fingers.

The user assembles the MEMS device model in the 3D view 300 by connecting representations of the selected components 111, 113 and 115. The representations of the components are generated by 3D view generators 112, 114 and 116 respectively associated with the selected components. The 3D design environment saves the connection information that indicates how the components were connected by the user in the 3D view. The data structure underlying the model constructed in the 3D view 300 is referred to as a multi-physics or MEMS device model and contains references to the constituent components 301, 302, 303, 304 and 305, their underlying behavioral models, and data that indicates how the components 301, 302, 303, 304 and 305 are connected. The MEMS device model 150 constructed in the 3D view may be directly exported to a system modeling environment without additional meshing to form part of a system model of a MEMS device.

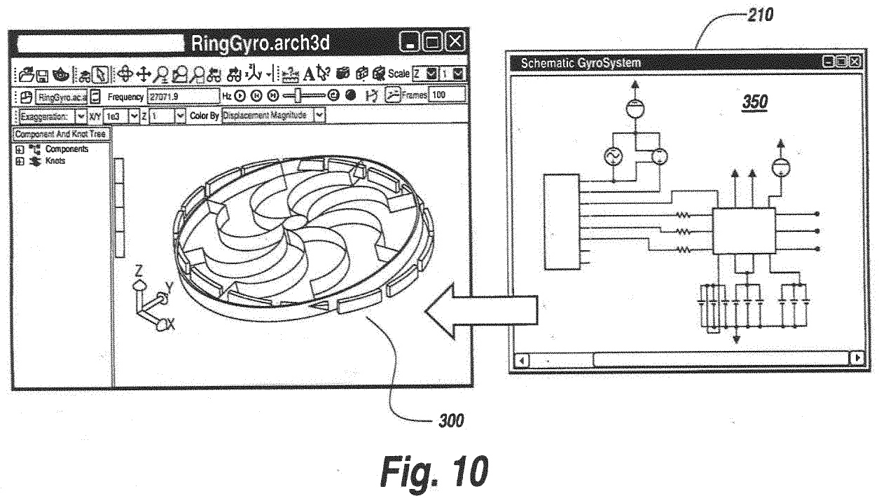

One of ordinary skill in the art will appreciate that the MEMS component library 110 may include any number of components and corresponding 3D view generators. The number of components and corresponding 3D view generators illustrated in FIG. 10 are for illustrative purposes only and should not be deemed as limiting.

FIGS. 2A and 2B depict the 3D view 300 used to create a MEMS device model in greater detail. FIG. 2A depicts an empty 3D view 300 generated by the 3D schematic editor 140. A user creates the MEMS device model by selecting components from a MEMS component library 110 and arranging them in the 3D view 300. FIG. 2B displays a parameter box 204 listing configurable parameters associated with a selected MEMS component.

There are two categories of parameters that are relevant for multi-physics device design. The first category consists of the material properties and geometric parameters that are determined by the manufacturing process. The second category consists of the dimensional parameters of the components of the multi-physics device model, such as length, width, number of comb fingers, etc., that are determined by the user, i.e. the MEMS engineer.

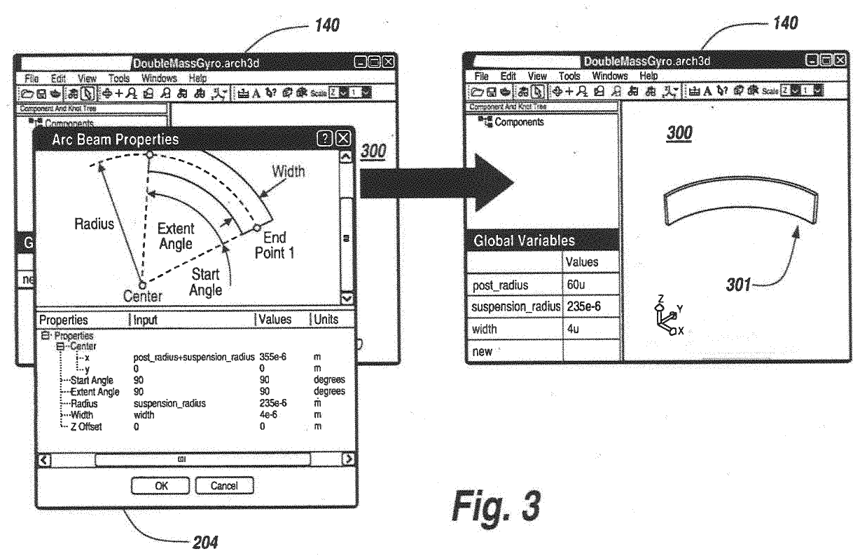

FIG. 3 illustrates an arc beam as an exemplary MEMS device model component 151 selected from the MEMS component library 110. The user 10 defines the parameters of the arc beam using a pop up menu 204. Once the parameterization of the component 151 is complete, a 3D view of the arc beam component 301 is depicted in the 3D view 300. The user 10 may select additional components and generate corresponding 3D views for the selected components. The 3D views can be connected (mechanically, electrically, optically, etc.) based on user selection or automatically by identifying touching component faces in the corresponding 3D models. For example, a beam and a rigid plate component may be connected automatically by recognizing that their shapes touch or intersect each other. At the end of the design process, a 3D view 300 of the entire MEMS device model 150 is provided to the user 10.

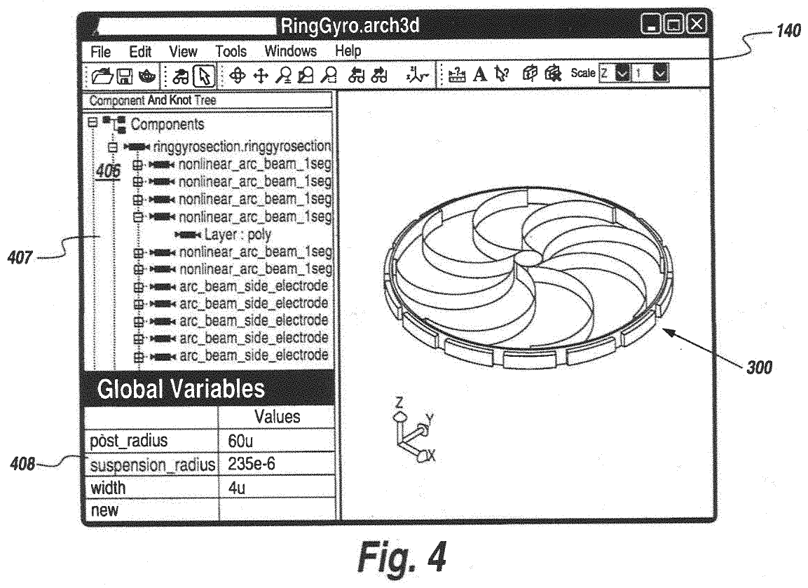

FIG. 4 illustrates an exemplary 3D view of a ring gyroscope model 300. The 3D view 300 is a composite of individual 3D views of selected MEMS device model components. As further illustrated in FIG. 4, a list 406 of all MEMS components used in the MEMS device model 150 is displayed in a window 407 of the 3D design environment 100. The list of the components may be organized hierarchically to better illustrate the structure of the MEMS device model 150. The user 10 may select one or more components from the list 406 and see the global variables associated with the selected component(s) in a window 408 of the 3D design environment 100.

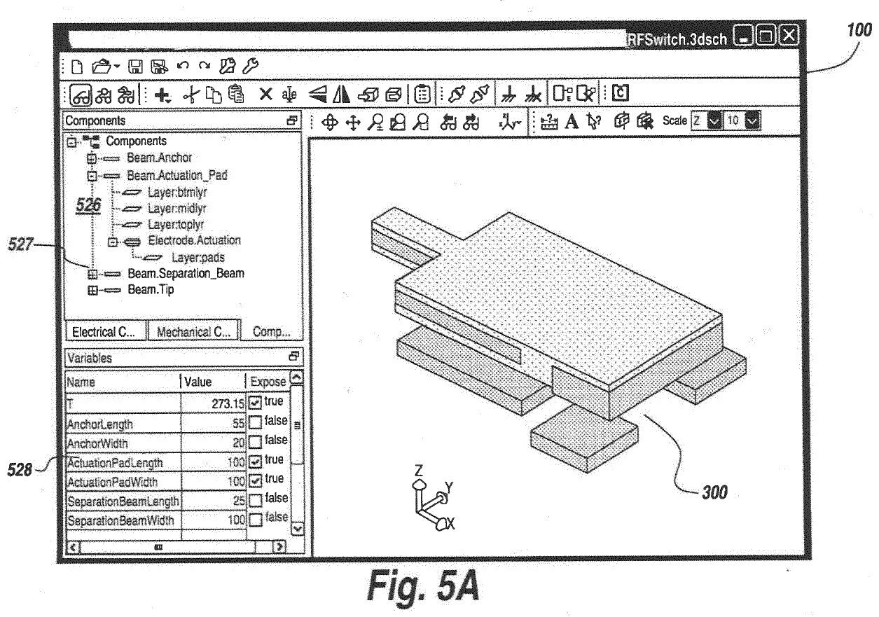

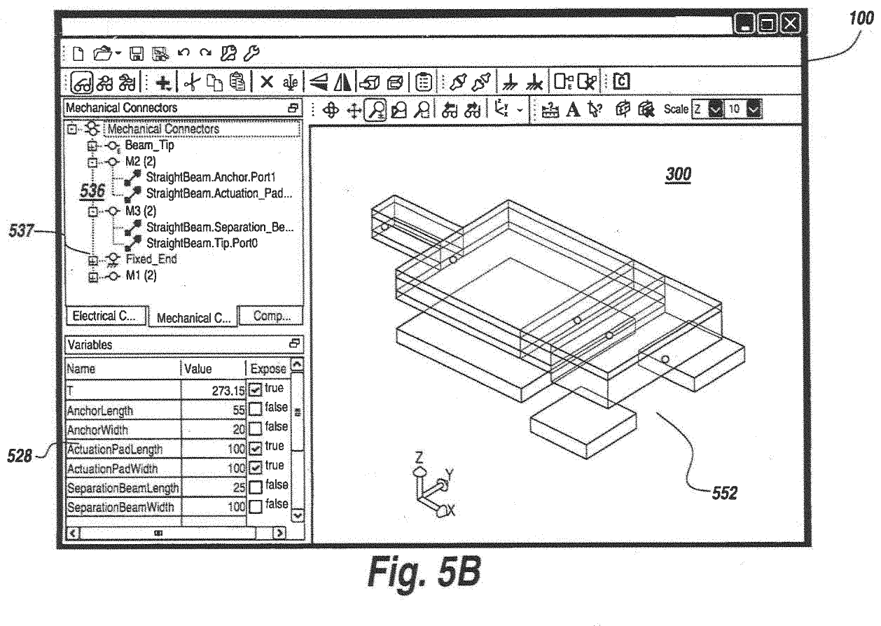

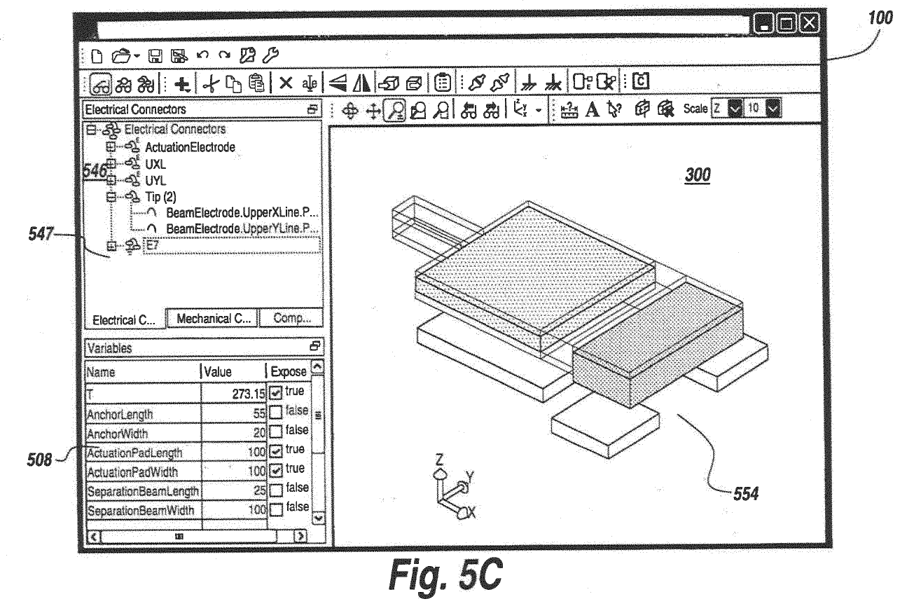

FIGS. 5A-5C illustrate an exemplary the 3D view 300 of another MEMS device model, i.e. a Radio Frequency (RF) switch. As shown in FIG. 5A, a list 526 of all components depicted in the 3D view of the RF switch 300 is displayed as a tree structure on a window pane 527 of the 3D design environment 100. The list 526 of the components may be organized hierarchically to better illustrate the structure of the view of the 3D view of the RF switch 300. The user 10 may select one or more components from the list 526 and see the global variables associated with the selected component(s) on a window 528 of the 3D design environment 100. As it can be seen from the component tree, the RF switch illustrated in FIG. 5A includes 4 basic building blocks, i.e. components: one anchor and 3 beams.

FIG. 5B illustrates the mechanical connectors 552 depicted in the 3D view of the RF switch 300 illustrated in FIG. 5A. A list of the mechanical connectors 536 is displayed in a tree view in a window 537 of the 3D design environment 100. The view 352 of the mechanical connectors 536 illustrates which components are linked together. Visual cues may be used to illustrate the connections between mechanical components. For example, in FIG. 5B the mechanical components are illustrated partially transparent and the mechanical connectors between the components are indicated by highlighted dots. It should be appreciated that connected components would move together as a single piece.

FIG. 5C illustrates the electrical connectors of the RF switch illustrated in FIG. 5A. A list of the electrical connectors 546 is displayed in a tree view in a window 547 of the 3D design environment 100. The electrical connectors view 554 illustrates electrical connectivity among components using visual cues such as colors, opaque/transparent display, etc. Again, it should be appreciated that connected components would move together as a single piece. For example, electrical layers may be shown as solid pieces in the 3D view of the device model.

In addition to tailoring the dimensions of the components of a multi-physics device, it is sometimes necessary to tailor the fabrication process to a particular multi-physics device in order to achieve the design goals. Thus the fabrication process is an important “free parameter” in multi-physics device designs that often needs to be refined as the development progresses. The flexibility to change the description of the fabrication process is missing from conventional IC design environments. In multi-physics device design, the parameters of the process description can be varied as part of the design, thus the models must be parameterized with respect to the process parameters as well.

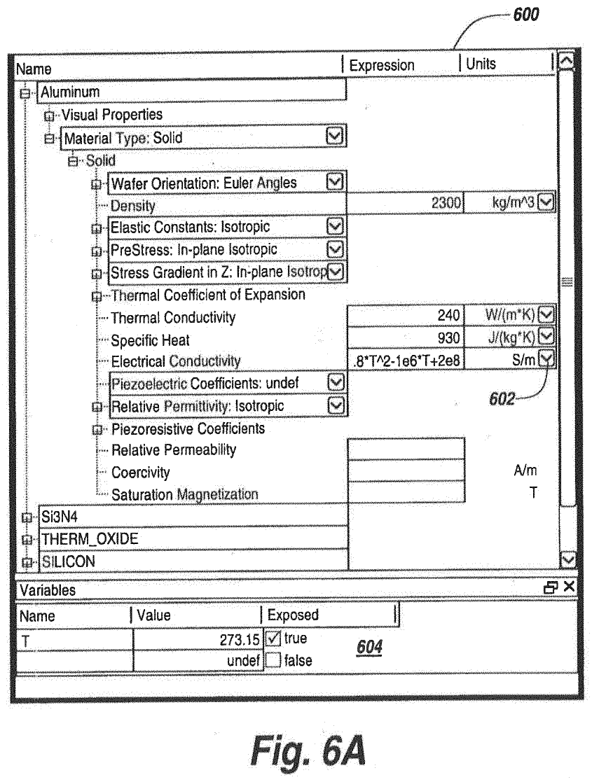

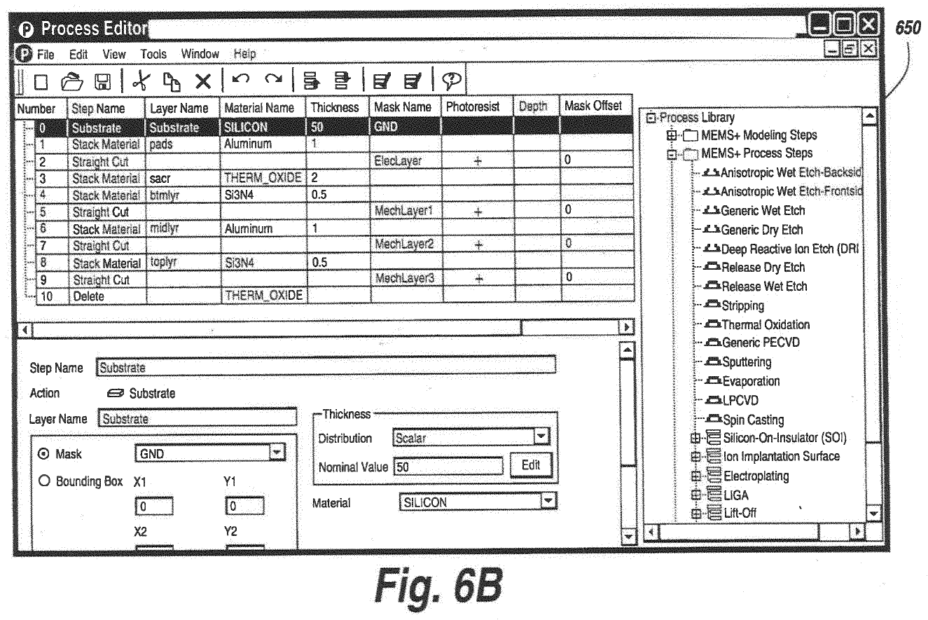

The 3D design environment addresses the specific needs of users, i.e. MEMS designers, to parameterize process parameters by providing two editors that are used to specify all relevant fabrication-specific data. The first editor, the material property editor 600, is shown in FIG. 6A. The material property editor 600 is used to create a material database that contains all relevant physical as well as visual properties used in the 3D design environment 100. Material properties may be defined as absolute values, variables or algebraic equations. A combination of variables and algebraic equations allows for properties to be mutually dependent on other properties, environmental variables, e.g. temperature and humidity, or entirely abstract variables such as the equipment settings of a given fabrication process. The user 10 can choose which variables are to be exposed to other users. For example, FIG. 6A illustrates that the electrical conductivity 602 of aluminum is given by an algebraic expression that depends on the temperature T. At the bottom of the FIG. 6A, the user chose to “expose” T to other users by checking the corresponding box 604 on the material property editor 600.

The second editor in the exemplary 3D design environment is known as a process editor and is shown in FIG. 6B. The process editor 650 enables the full parameterization of the behavioral model for the complete MEMS device that is shared with the system modeling environment with respect to manufacturing and design-dependent variables. The process editor 650 is used to define the sequence of the multi-physics device fabrication steps. The underlying process data includes all relevant information about the layer stack, such as the layer order, material type, thickness and sidewall profile. The process data is dependent on a material database. Each of the layers in the process data specifies a material type that must exist in the corresponding material database.

The MEMS device model 150 is a system model of the MEMS device designed in the 3D Design Environment 100. The components 151, 152, 153, 154 and 155 correspond to the components 301, 302, 303, 304 and 305 that are visible in the 3D view 300 of the MEMS device model 150 that were selected from the MEMS component library 110. The MEMS device model 150 also contains links 156, 157, 158 and 159 that define the connectivity among the components 151, 152, 153, 154 and 155.

After the MEMS device model 150 is completed in the 3D design environment 100, the user 10 assigns a schematic symbol 236 to the MEMS device model 150. The MEMS device model may be exported to the system modeling environment 200 in the form of the schematic symbol 236 and a netlist that conveys connectivity information among components. The combination of the schematic symbol 236 and the netlist 237 is referred to as MEMS device 235 in the system modeling environment 200 in FIG. 1. The schematic symbol 236 represents the MEMS device model 150 in a schematic being simulated in the system modeling environment 200.

The use of the schematic symbol that represents the created MEMS device model provides a way to control the amount of information presented to the IC designers who are responsible for designing the electronic circuits that surround a MEMS device. IC designers do not need to see all of the components that comprise the MEMS device in their schematic. Moreover, there are situations in which the MEMS designers and IC designers work for different companies and it is desirable to protect the intellectual property of the MEMS device design by hiding its details from the IC designers. Therefore, the 3D design environment enables the MEMS designers to export a single symbol that represents the MEMS device to the system modeling environment and expose as ports to that symbol only the inputs, outputs and parameters that are of interest to the IC designers.

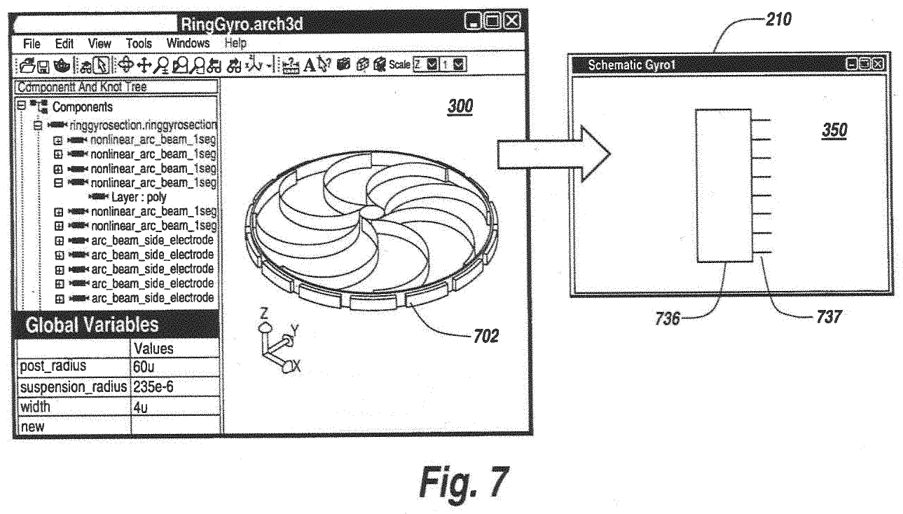

FIG. 7 illustrates a completed 3D view 300 of an exemplary MEMS device model 150 in the 3D design environment 100, e.g. a ring gyro, and a corresponding schematic symbol 736 in the schematic view 350 in the system modeling environment 200. As noted above, the user 10 also specifies which parameters of the MEMS device model 150 will be exposed in the system modeling environment 200. The exposed parameters are illustrated as the pins 737 of the schematic symbol 736. The pins 737 of the schematic symbol 736 represent the electrical connections needed to link the schematic symbol 736 with one or more other components in a schematic in the system modeling environment. Additional connectors to other physical degrees of freedom inside the MEMS device model 150 may be exposed based on user selection. Global variables of the MEMS device model 150 are preserved as parameters of the MEMS device symbol 736.

As illustrated in FIG. 1, the system modeling environment 200 includes a schematic editor 210, a circuit simulator 220, and a system component library 230. As discussed further herein, some or all of the system component library 230 may be user-defined and modified. In one embodiment, an additional component library plugin (not shown) allows users to customize the library of components through an editor. The schematic editor 210 is used to create and/or edit a system model 250. A user selects the MEMS device 235 and the electronic components 231 and 233 from the system component library 230 and places them in a schematic view 350 where the symbolic representations 232, and 234 of the model components 231 and 233 are joined with the schematic symbol 236 representing the MEMS device model 150 and displayed in two dimensions to the user. The MEMS model may therefore be an assembly of components from a user-defined library. The user also specifies or draws connections between the symbols 352, 354, 356 and 358 in the schematic view 350.

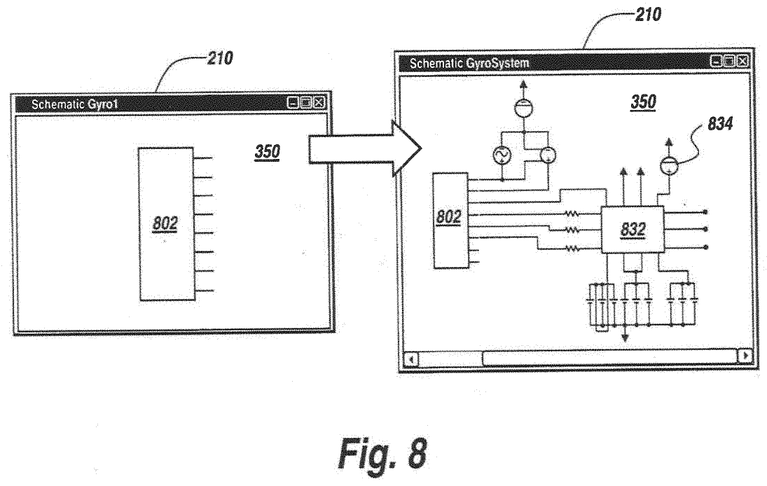

FIG. 8 illustrates the schematic view 350 of an exemplary complete system model 250. A schematic symbol 802 imported from the 3D design environment 100 is connected to schematic symbols 832 and 834 representing components of the system component library 230 added to the exemplary MEMS device 235 in the system modeling environment 200. The user configures the parameters of the selected components and interconnects their ports with the imported symbol representing the MEMS device created in the 3D design environment to create a schematic of the entire device in the schematic view 350. One of ordinary skill in the art would appreciate that the user may be the same as the user designing the MEMS device model, i.e. the MEMS designer. Alternatively, the user may be a user designing the schematic view of the MEMS device model, i.e. the IC designer. It should also be appreciated that the components may be selected and configured prior to the importation of the schematic symbol from the 3D design environment.

Alternatively, a user in the 3D design environment may request a simulation and the symbol representing the MEMS device may be automatically exported, connected in a schematic, and simulated in the system modeling environment without additional user action.

When forming the schematic model in the schematic view 350, the symbols representing electronic components such as transistors, resistors, inductors and capacitors are connected to create the desired circuit behavior. The symbols that represent the electronic components have ports, or pins, that can be connected by wires to pins of other components. Each pin has a voltage and transfers current into or out of the component. In the schematic capture, components may represent entities from other physical domains, such as masses, plates, magnets, lasers, optical lenses, electrostatic comb structures and electrodes. The symbol ports of components represent inputs for electrical, mechanical, magnetic, fluidic, or optical sources, or can be input or output control pins for mechanical degrees of freedom, i.e. translational and rotational motions.

The schematic editor 210 maintains an underlying system model 250, which corresponds to the schematic view 350. The system model 250 contains references to particular instances 251, 252, 253 and 254 of the system components 231, 233 and 235. More than one instance may reference the same model component. The system model 250 also contains the connections 255, 256 and 257 between the component instances 251, 252, 253 and 254.

The schematic editor 210 is also used to specify the values of the parameters that define each schematic component instance 251, 252, 253 and 254. The parameters for each component 231, 233 and 235 are part of the component definition. The component definition of the MEMS device 235 may include all global parameters of the MEMS device model 150. The component parameters of the MEMS device 235 may include geometrical dimensions such as position, orientation, length, width and height, layer names or material properties like density and modulus of elasticity. In one instance changes of the parameters in components of the MEMS device 235 in the schematic editor 210 results in an automatically synchronized update of the 3D View 300.

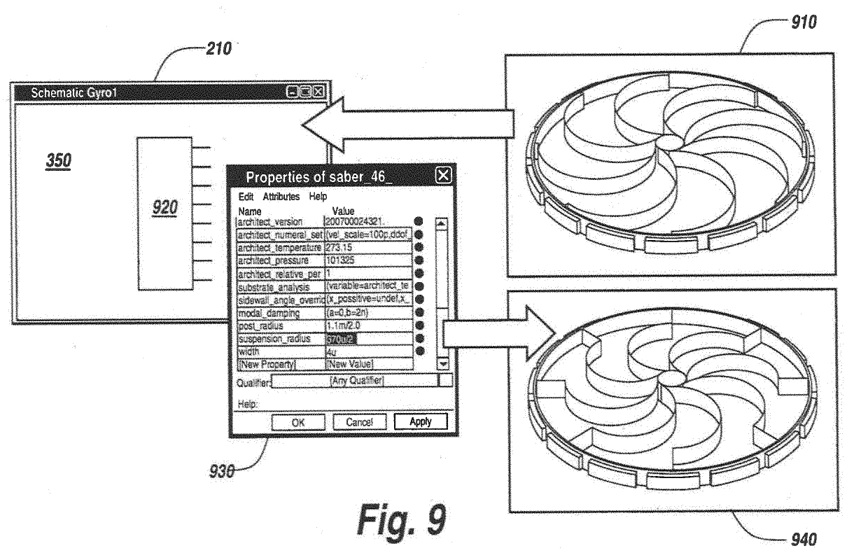

FIG. 9 illustrates an exemplary 3D view 910 of a MEMS device, a ring gyro. The MEMS device model 150 for the ring gyro is exported into the system modeling environment 200. After selection by the user via the schematic editor 210, a symbol 920 that represents the MEMS device model 150 is displayed in the schematic view 350. The user may view and adjust parameters of the schematic symbol 920 representing the ring gyro 910 using the pop-up window 930. Those skilled in the art will recognize that the pop-up window 930 is provided for illustrative purposes and should not be construed as limiting as other mechanisms for adjusting parameters of the schematic symbol 920 may be used without departing from the scope of the present invention. The changes made in the schematic view 350 may be conveyed to the 3D design environment 100, and an updated 3D view 940 of the ring gyro may be displayed on the display device 14.

The system modeling environment 200 also includes a circuit simulator 220. The circuit simulator 220 is used to perform simulations of the system model 250 represented in the schematic view 350 by numerically integrating a system of coupled ordinary differential equations. The user may run a simulation of the schematic model 250 in the circuit simulator 220 that will evaluate the MEMS device behavioral model at each simulation point, i.e. time step or frequency. The user may run DC, AC and transient simulations of the model to confirm the device performance. The execution of the simulation produces a simulation result 240. The simulation result 240 is transferred back into the 3D design environment 100 in order to be displayed using the 3D simulation result visualizer 120. The 3D simulation result visualizer 120 programmatically provides continuous updates of the individual MEMS components' (301, 302, 303, 304 and 305) 3D views, resulting in an animation of the mechanical motion of the 3D view 300 of the entire MEMS device model 150.

As illustrated in FIG. 10, a 3D simulation result visualizer 120, provided in the 3D design environment 100, uses the simulation result 240, the system model 250 and the MEMS device model 150 to provide a 3D view 300 of the simulation result 240 to the user 10. The simulation result 240 from a simulation of system model 250 depicted in the schematic view 350 is fed to the 3D simulation result visualizer 120. The simulation result visualizer 120 works in conjunction with 3D view generators 112, 114 and 116 to produce a 3D view 300 of the simulation result 240 by progressively altering the 3D view 300 to reflect changes in position over time, frequency or any other physical quantity being varied during the simulation of the system model 250.

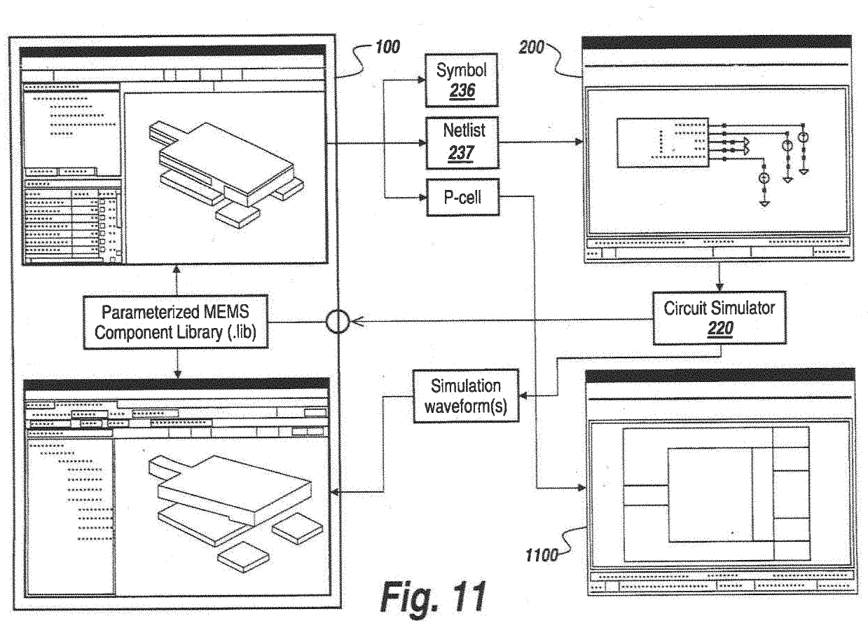

FIG. 11 illustrates an alternate overview of the design process discussed herein including the 3D design environment 100, the system modeling environment 200 and a layout editor 1100. As discussed above, the user may create a 3D MEMS device model 150 representing the MEMS device in the 3D design environment 100. After the MEMS device model 150 is completed, it can be exported to a system modeling environment 200. The model export involves the steps of creating a schematic symbol 236 representing the MEMS device, and exporting both the MEMS device symbol 236 and corresponding device model 150 in a format that is compatible with the system modeling environment 200. The exported device model 150 may be in the form of a netlist 237, i.e. a data structure that describes a system model. The created symbol 236 may have electrical connection pins needed to link the MEMS device symbol 236 with other schematic symbols in the system modeling environment 200. Additional connectors to other non-electrical degrees of freedom inside the MEMS device model may optionally be exposed in the MEMS device symbol 236. All global variables used in the MEMS device model 150 may be preserved as parameters of the created schematic symbol 236. These parameters may include geometrical, material or any other type of global variables used during the device definition in the 3D design environment 100.

In the system modeling environment 200, a user forms a system model 250 by connecting the MEMS device 235 represented by the symbol 236 and other components 231, 233 and 235 from the system component library 230 in a schematic view 200. Upon completing the system model 250, the user runs a simulation of the system model 250 using the circuit simulator 220. The simulation result 240 is exported to the 3D design environment 100 to be used in an animation of the 3D view 300 of the MEMS device model 150. When the user is satisfied with the design, the user may export a parameterized layout cell (p-cell) to a layout editor 1100.

The behavioral models of the multi-physics devices discussed above are sufficiently sophisticated to fully represent the behavior of the multi-physics devices, capturing, for example, cross-coupling between the mechanical degrees of freedom. These behavioral models are more accurate than reduced-order models or look-up tables. The behavioral models and layout p-cells are fully parameterized both with respect to manufacturing-dependent variations and geometric attributes of the design, enabling design and yield optimization studies in the EDA environment. The automatic hand-off and cross-linking between the multi-physics devices and system modeling environments eliminates inevitable human errors that arise in any manual hand-off process.

Those skilled in the art will recognize that the user 10 may be separated from the computing device 12 via a network such as the Internet. Similarly, the components used by the 3D design environment may appear in a distributed manner over a network rather than being consolidated in a single computing device 12 and the multi-physics device components may be stored in a location other than in a component library.

Compact Model Generation

The 3D design environment described above may be adapted for compact model generation. As a non-limiting example of compact model generation provided by embodiments taking place in a 3D design environment, a MEMS device may include components with two functionalities, namely deformable mechanical structures and electrodes. A 2D polygonal description from which a compact model is to be built, such as but not limited to a GDSII file, may group each functionality on a different layer. For example, components that are deformable mechanical structures may appear on layer A of the 2D polygonal description while the electrodes may be grouped on layer B of the 2D polygonal description. The component library in the 3D design environment may have four types of components that have one of those two functionalities: a flexible 3D rectangular plate, a flexible 3D triangular plate, a rectangular electrode and a triangular electrode. For example, a user of the 3D design environment may specify in the component library via a user interface that flexible components are expected to be found on layer A and electrodes are expected on layer B. Further, for each of the four types of components, the user may configure the components in the component library by specifying on which layer the components can be found by specifying the location via a user interface. Continuing with the above example, the user may specify that a flexible 3D rectangular plate will appear on layer A and a flexible 3D triangular plate will also appear on layer A. Similarly, the user specifies that the rectangular electrode and triangular electrode both will appear on layer B of the 2D description.

Subsequently when the 2D description is imported into the 3D design environment to build a 3D model, the 3D design environment examines each layer of the description. For each layer, all the components in the library that are available for that layer based on the layer's functionality (e.g. flexible/deformable mechanical structures, electrodes, etc.) are identified and the component most appropriate to represent the geometry is selected for the device model by applying a geometric criterion to the layer data. In the above example, if a rectangle is present on layer A, the 3D design environment knows that it is a deformable mechanical structure because of the previous user specification that deformable structures will be on layer A. Accordingly the 3D design environment attempts to find a component meeting that geometric criteria (rectangle) that is assigned to that layer in the library. In the above example, the rectangle on layer A is interpreted as a flexible 3D rectangular plate as a result of the previous configuration of the flexible 3D rectangular plate component in the library. Similarly, if a rectangle is present on layer B, it will be interpreted by the 3D design environment as a rectangular electrode due to its configuration. The same principle is applied to create a single component corresponding to identified patterns of geometric shapes, for example, combs.

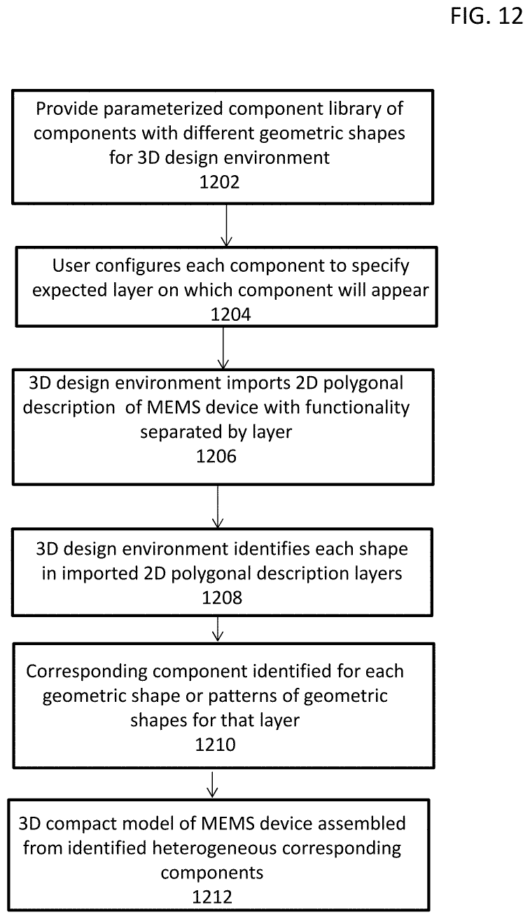

FIG. 12 is a flowchart of an exemplary sequence of steps followed by an embodiment of the present invention to create a 3D compact model from a 2D polygonal description in a 3D design environment. The sequence begins by providing a library of parameterized components with different geometric shapes in a 3D design environment (step 1202). The user configures each these components to specify the layer of a 2D polygonal model description on which the component is expected to appear (step 1204). For example, the 2D polygonal description may be a GDSII format which is a binary file format and the user may specify that a rectangular electrode is expected to be on layer B of the 2D description. The sequence continues with the importing of a 2D polygonal description of a MEMS device model into the 3D design environment (step 1206). The 3D design environment examines the imported 2D polygonal description and identifies each geometric shape on each layer (step 1208). The 3D design environment then identifies the corresponding component with that geometric shape or patterns of geometric shapes (e.g. combs) assigned to that layer in the component library (step 1210). Once all the corresponding components have been identified, they are assembled in the 3D design environment to create a 3D compact model (step 1212). In one embodiment, the assembly of the corresponding components takes place programmatically. In another embodiment the user manually connects the displayed 3D component representations in the 3D view to assemble the model.

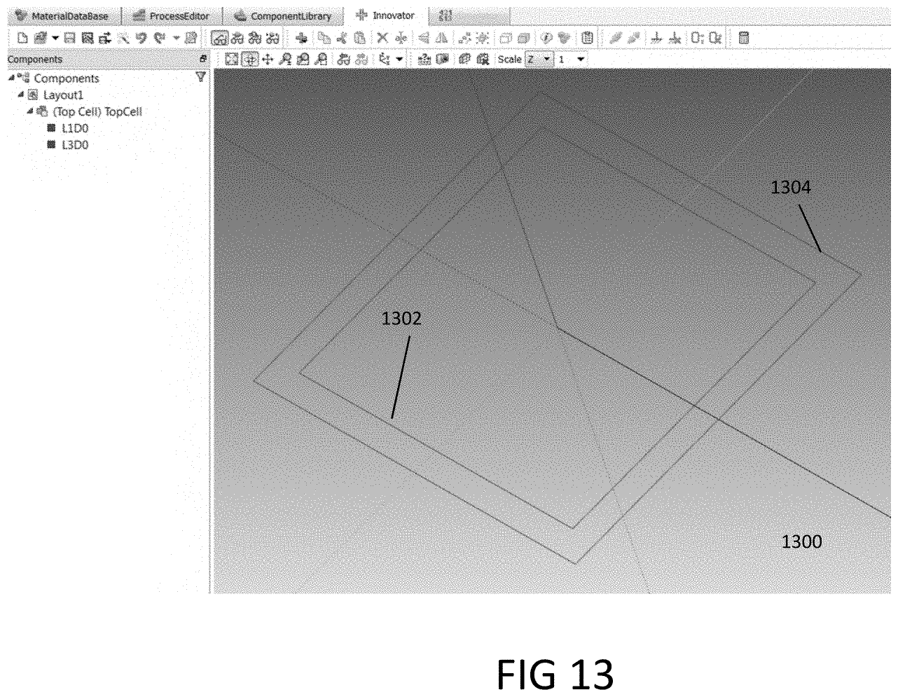

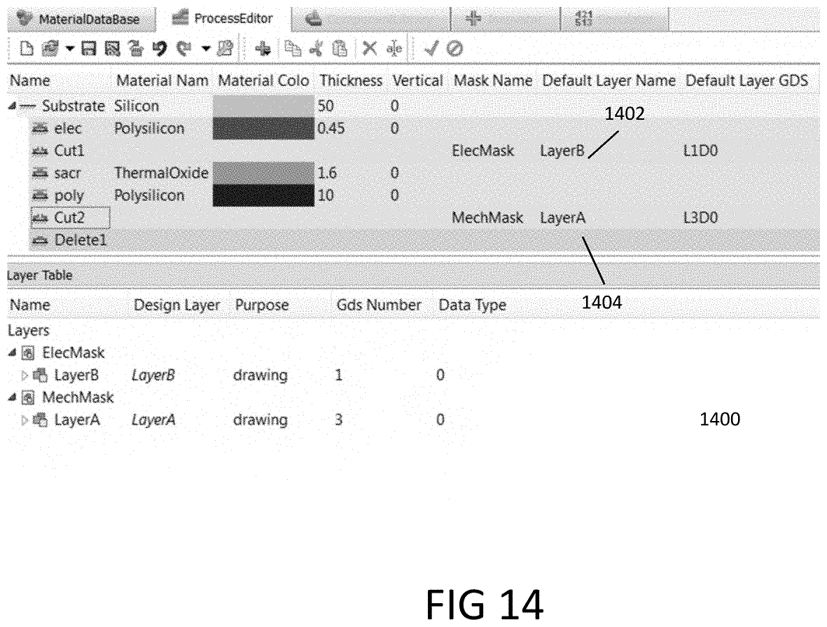

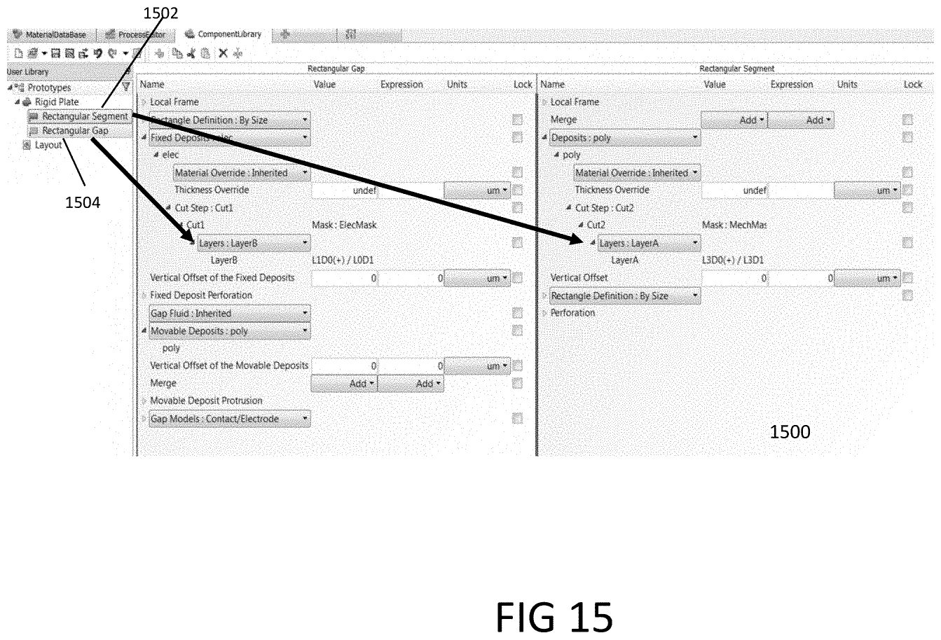

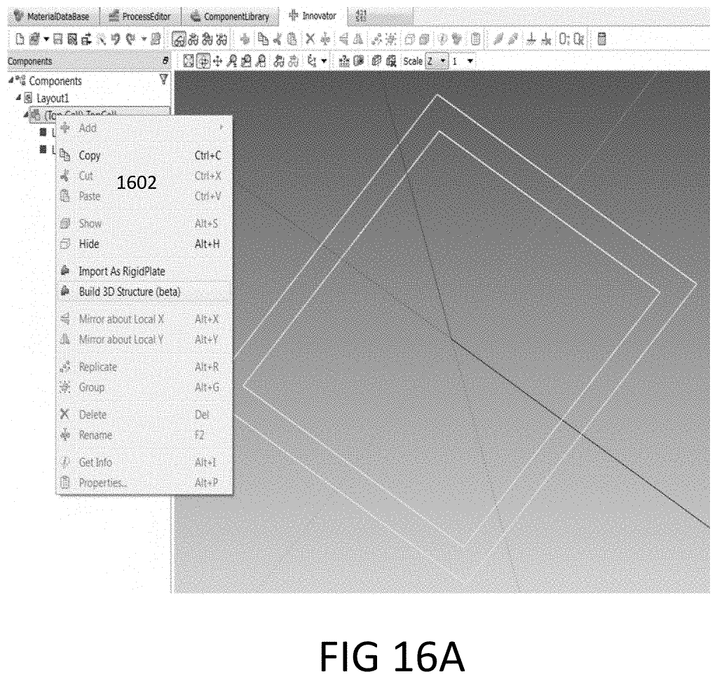

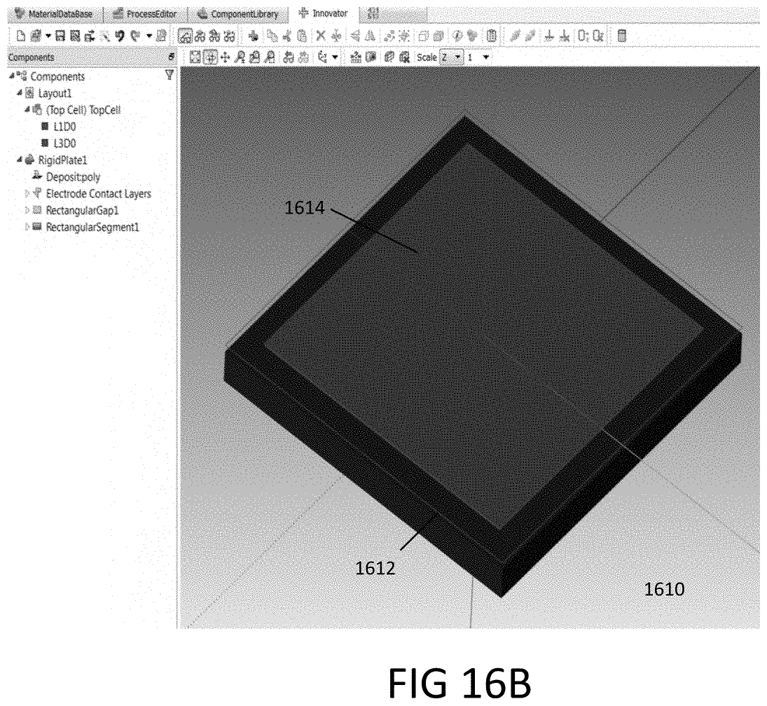

FIGS. 13-16B provide illustration as to how similarly shaped components are distinguished in the 3D design environment. FIG. 13 depicts a 2D layout view 1300 of two rectangular shaped components an electrode (the inner rectangle) 1302 and a mechanical part (the outer rectangle) 1304. FIG. 14 depicts a process editor 1400 used to describe the fabrication process of the MEMS device as a succession of deposit and patterning steps of different materials. The patterning, or cut steps, are associated with a mask. Each mask is the result of Boolean operations (add/subtract) of layers. The user may specify 1402 in the process editor 1400 that the electrical mask used to pattern the 0.45 um polysilicon deposit is only constituted by layer B and may specify 1404 that the mechanical mask used to pattern the 10 um polysilicon deposit is constituted by layer A. FIG. 15 depicts a UI 1500 for a component library of the 3D design environment where each type of component may be configured by a user to specify the layer on which the component should appear. It should be noted that a single component may be suitable for more than one layer and more than 1 layer may be selected through the user interface for the component. For example, in UI 1500 the user has configured the rectangular segment component to appear on layer A and the rectangular gap component 1504 to appear on layer B. These configurations allow the 3D design environment to correctly interpret the imported 2D polygonal description of the MEMS device model. FIGS. 16A-16B depict an exemplary model creation in the 3D design environment that uses the configurations specified in FIG. 15. In FIG. 16A, the user utilizes a pull-down menu 1602 to start model creation. FIG. 16B depicts an exemplary created 3D compact model 1610 with both a rectangular segment component 1612 and a rectangular gap component 1614.

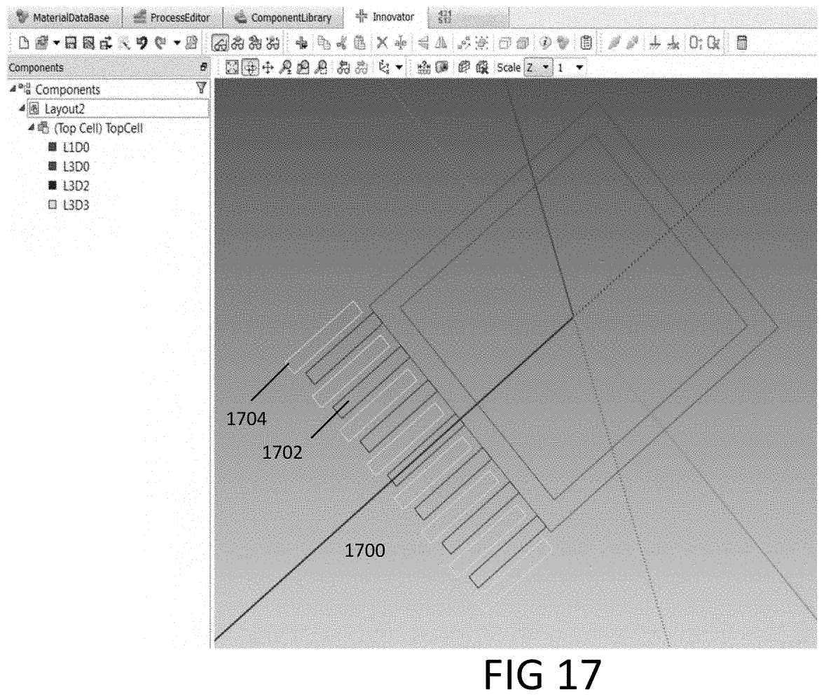

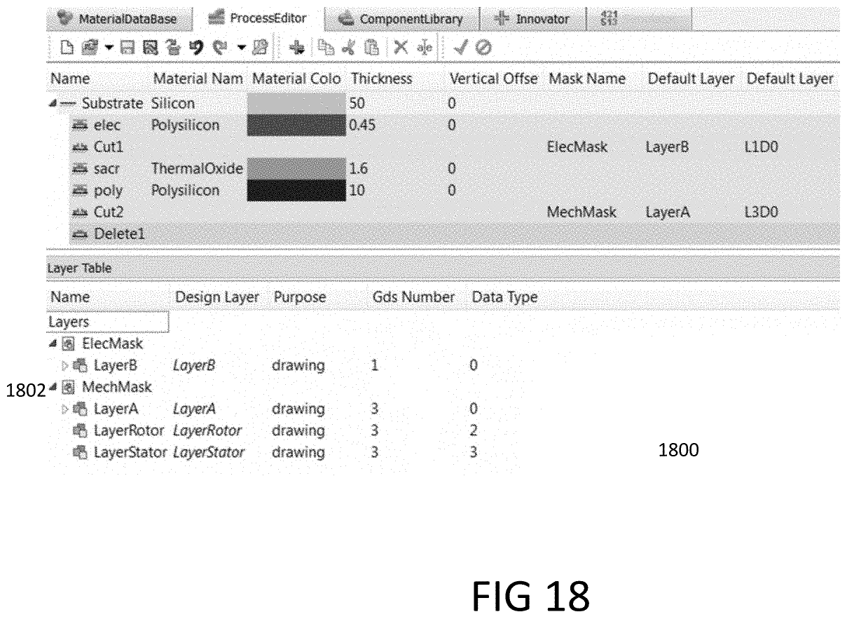

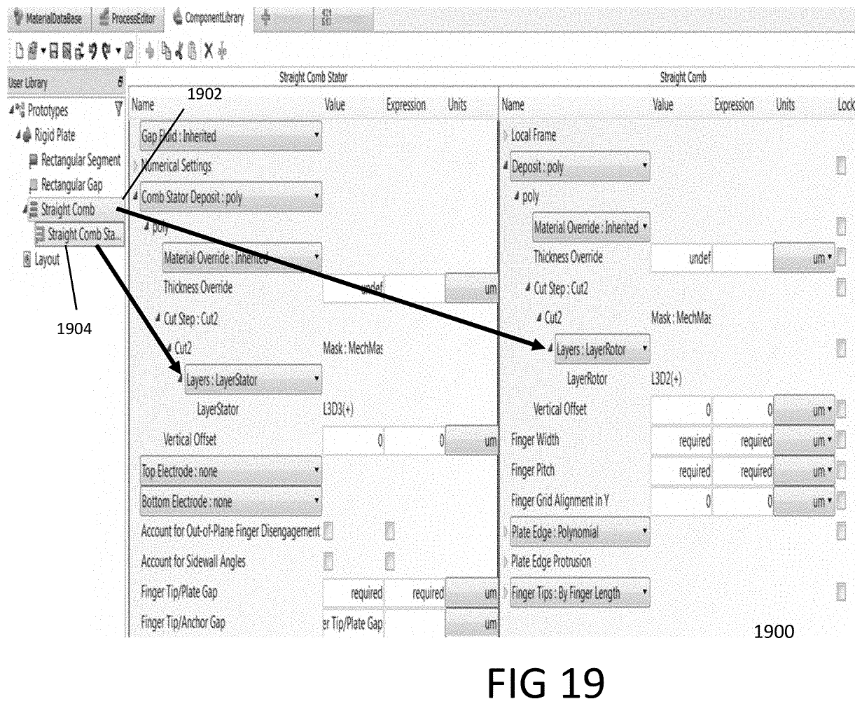

FIG. 17 depicts another example of model creation in an embodiment. FIG. 17 depicts an exemplary electrostatic comb 1700 reflected in a 2D layout with several rectangles on different layers. The model has two types of rectangle components that need to be respectively identified as combs rotor 1702 and stator 1704 respectively, in addition to the rectangles already present in FIG. 13. The process editor 1800 in FIG. 18 may be used to describe the mechanical mask 1802 patterning the 10 um polysilicon deposit, as being the union of layerA, LayerStator and LayerRotor. This information will be interpreted by the 3D virtual design environment as: any polygon found on layerA or LayerStator or LayerRotor will be made of 10 um polysilicon material. FIG. 19 depicts an exemplary UI 1900 for the component library through which the user may specify the layer for the component. For example, in FIG. 19, the stator 1902 is configured by the user to appear on LayerStator (layer 3 and be data type 3) while the rotor 1904 is configured to appear on LayerRotor (layer 3 and be data type 2).

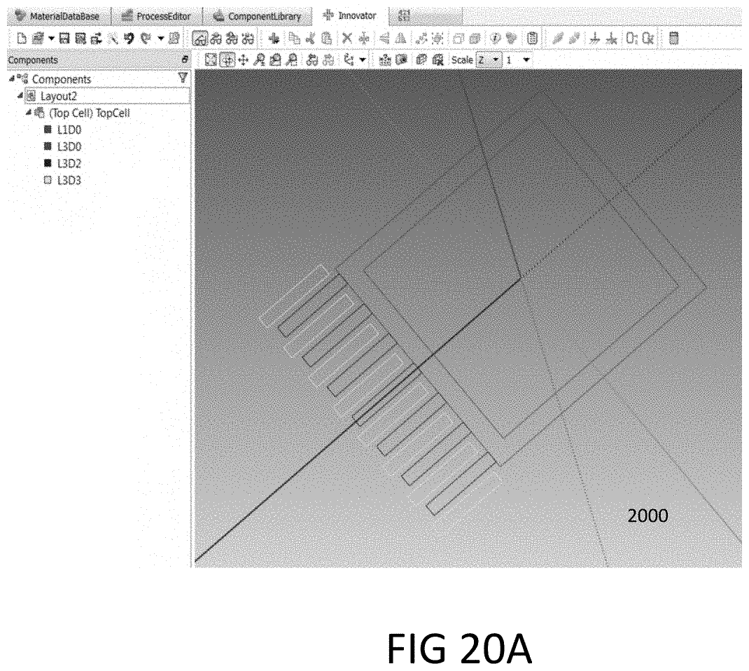

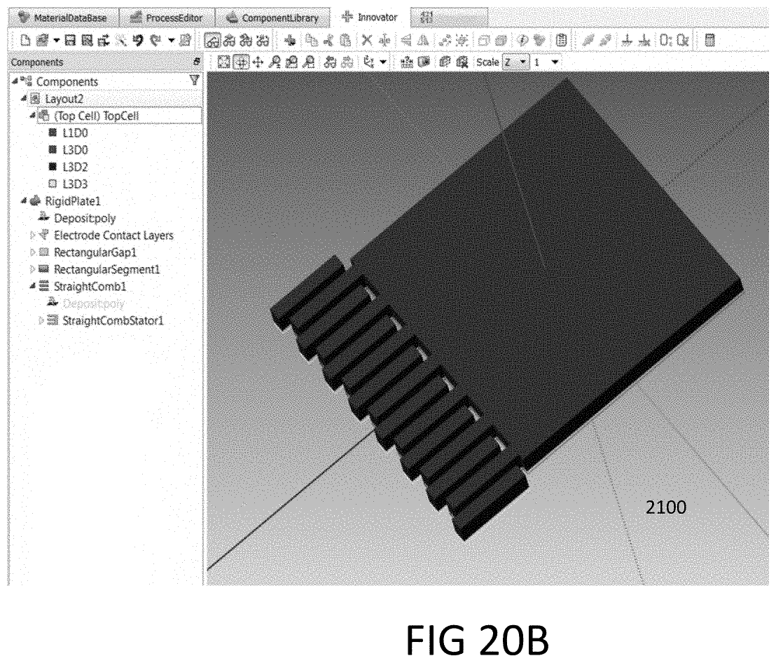

Once the component configuration is performed by the user, the interpretation of the 2D layout 2000 depicted in FIG. 20A (but represented in GDSII format and imported into the 3D design environment) leads to the automatic generation of the model 2100 shown in FIG. 20B. Therein, the rectangle on layerA (L3D0) is imported as a rectangular segment. The rectangle on layerB is imported as a RectangularGap (not visible on the 3D view of the picture). All the rectangles present on LayerRotor (L3D2) are converted to a single StraightComb component, each rectangle representing a finger of the comb. The criterion used to decide whether to create a single component or more is to create the least possible number of components capable of representing exactly the geometry. Here, a single component is enough. The same logic applies to the StraightCombStator, made of all the rectangles present in LayerStator (L3D3). Also note the hierarchical relationship that is created: the stator is a child of the rotor, because in this behavioral model, a stator cannot be instantiated without a rotor.

It should be appreciated that this mechanism for creating compact 3D models can be generalized to a large number of components with different geometries and allows for complex compact model creation. This process can be tuned to different user needs. A requirement on the 2D polygonal representation is that the layers regroup geometries by functionality. If any modification of the 2D representation is required, operations to copy/paste and Boolean operations to regroup geometries on different layers based on functionality may be performed in a layout editor.

In one embodiment, an iterative procedure may be used to assemble components with hierarchical relationships. The 3D design environment makes a first pass through the 2D polygonal description to interpret the polygons on the different layers and corresponding components are created. In this approach, only components without prerequisites can be created on this first pass. For some polygons, no suitable corresponding components are found. Considering the previously created components may fulfill some prerequisites for components that were previously unavailable, these components are new candidates to become corresponding components during a second pass performed on the remaining polygons. In an embodiment, this process can be iterated as long as some polygons remain to be created, allowing complex hierarchical relations between components.

In another embodiment, the same information used to create the 3D model may be used in reverse from the component library when creating a 2D polygonal description from a 3D model.

In one embodiment, an embedded solver may be provided to the 3D design environment that can run analyses on the model without requiring an external EDA tool. In this case, only the MEMS, and not its surrounding IC is simulated.

### Hybrid Model Generation Using Hexahedral Meshing

As noted above, the previously described approach to compact model generation can be supplemented by including meshed components in the created MEMS device model. More particularly, in order to enable the design of increasingly complex MEMS devices, the 3D design environment may be enhanced to provide the ability to discretize geometry using hexahedral mesh elements. In order to remain compatible with the approach of assembling geometrical elements from a library of available components to construct the structure of the device, and associating a physical model to each geometrical element, an additional ‘hexahedral mesh’ model choice may be introduced for various specified types of components. Users of the 3D design environment connect components modeled by hexahedral mesh elements to other components in the design by means of mechanical connectors located on those faces which are shared between meshed elements and the other components.

In one embodiment, the option of meshed plate components is provided in the 3D design environment. For example, the plate component may have a model parameter that allows the user to designate the plate as either rigid or as a hexahedral mesh component. The rigid plate option may be used for parts of the MEMS design that do not significantly affect the elasticity of the MEMS structure. Rigid bodies move through space without changing shape. The advantage of rigid bodies over deformable components such as the beam, serpentine, or quadrilateral is that the motion of a rigid body is described completely by no more than six mechanical degrees of freedom. When out-of-plane deformations are negligible or not of interest, modeling a component as a rigid plate may yield significant computational savings without sacrificing accuracy.

The hexahedral mesh option provided by the 3D design environment for the plate component allows the user to create a flexible plate with an arbitrary shape. The plate is flexible because it is meshed with hexahedral finite elements. A hexahedral-meshed plate is more accurate to use when out-of-plane motion in inherent to the operation of the device. However, a consequence of the added flexibility to the model is that analysis of the system may require extensive calculations because the mesh associated with the plate component may contribute a potentially significant number of degrees of freedom to the overall system. In one embodiment, plate components modeled with hexahedral mesh elements do not support child components, e.g.: a Gap or a Comb Stator.

In contrast to a rigid plate, which has one mechanical connector for all rigid plate segments, a meshed plate may have as many mechanical connectors as the user creates with face/rigid link position settings for the component provided via a graphical user interface in exemplary embodiments. This face/rigid link setting creates a mechanical connector that serves as a connection point for other components for each face added to the plate component by the user. Each face associated with the plate establishes a rigid link between the meshed plate and an adjacent component joined to the plate at that location. In one embodiment, the 3D design environment may provide information for each meshed plate including the display of the location of each created mechanical connector, the number of mechanical elements in the meshed plate, the number of mechanical nodes in the meshed plate, and the time required to mesh the plate.

In one embodiment, if a hexahedral mesh option is chosen for the plate, the 3D design environment may automatically select the most appropriate meshing algorithm based on the plate geometry. Alternatively, the user may specify the type of meshing algorithm. In an embodiment, the 3D design environment may include three types of meshing algorithms. A first orthogonal meshing algorithm may produce orthogonal or nearly orthogonal hexahedral (brick) elements. In an embodiment, plate geometry must consist of right angles or nearly right angles in order for orthogonal meshing to be employed. While there may be some tolerance on the angle for orthogonal meshing, rounded edges and non-zero sidewall angles are not supported.

A second non-orthogonal meshing algorithm may produce optimized extruded bricks as a hexahedral mesh is extruded from 2-D quadrilateral surface mesh. For this non-orthogonal meshing, the geometry can include rounded edges. However, this meshing algorithm may only support single deposit structures with no sidewall angle. A third meshing algorithm may also employ a hexahedral mesh extruded from 2-D quadrilateral surface mesh but one that supports different topographies, a number of deposits and/or a sidewall angle.

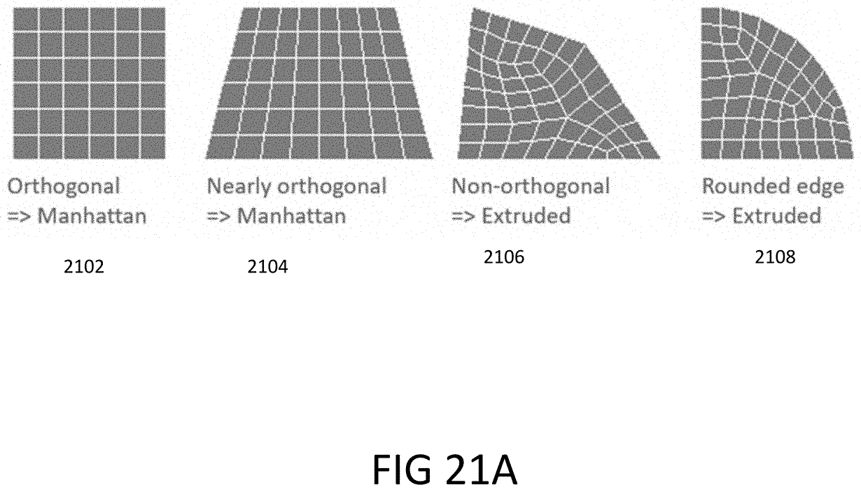

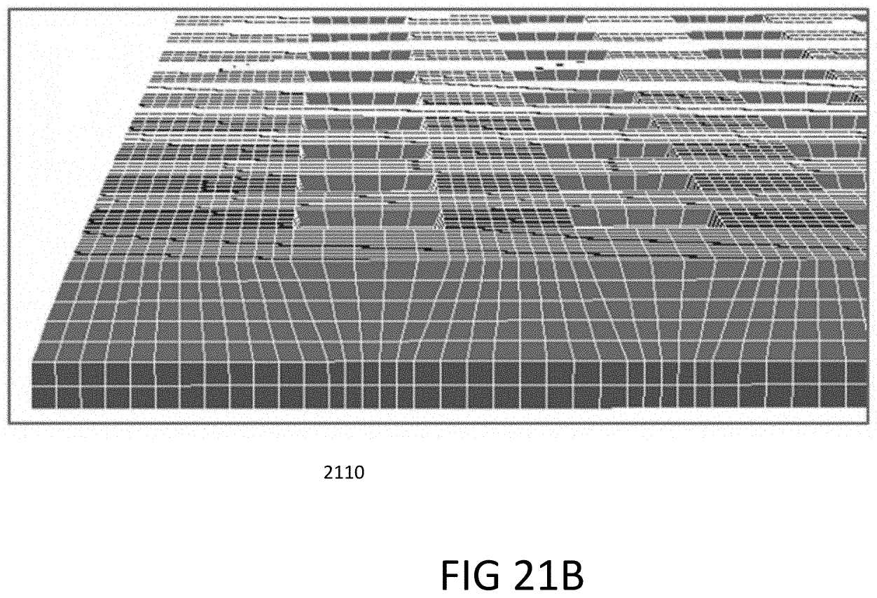

FIG. 21A depicts an exemplary output from two types of hexahedral meshing in an embodiment. Exemplary meshes 2102 and 2104 represent orthogonal or nearly orthogonal meshes producing a mesh of “Manhattan” bricks at right angles or near right angles. Exemplary meshes 2106 and 2108 represent non-orthogonal meshes extruded from a 2-D quadrilateral surface that produces a more rounded mesh. Similarly, FIG. 21B depicts another exemplary output from hexahedral meshing in an embodiment. More particularly, FIG. 21B depicts a mesh 2110 of advanced extruded bricks created on a multi-deposit device with sidewall angle.

In an embodiment, mesh generation occurs when the hexahedral mesh option is selected for a plate component by a user in the 3D design environment or upon certain property changes. Meshing time may depend primarily on the type of mesher algorithm selected by the 3D design environment but may also be impacted by element size and number of geometric features (e.g. perforations). It should be noted that no additional meshing time is required when the number of elements in Z is changed or upon a property change that does not affect the meshed geometry (e.g. creation of a face). In general, default properties allow faster meshing times.

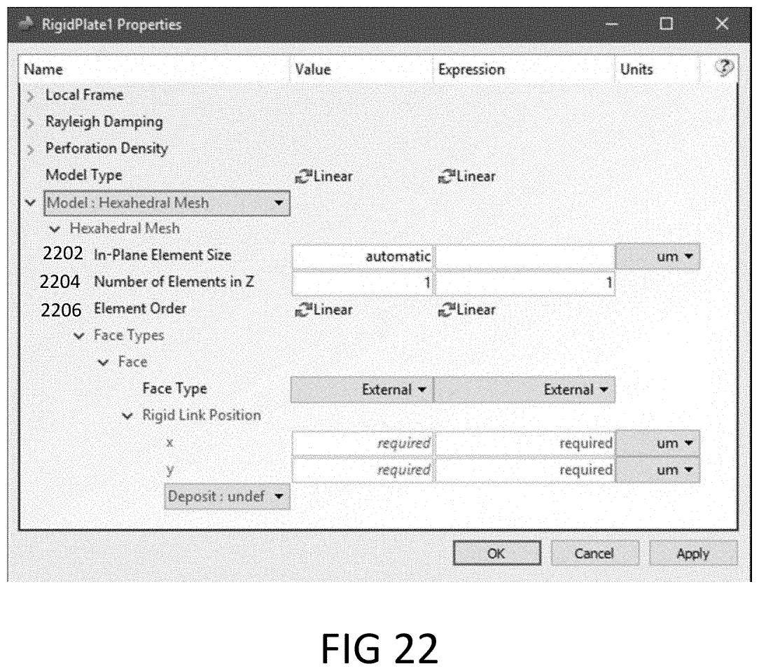

FIG. 22 depicts a graphical user interface provided by the 3D design environment configured to accept hexahedral meshing parameters for a plate in an exemplary embodiment. In one embodiment, the plate\hexahedral mesh option has the parameters of in-plane element size 2202, number of elements in Z 2204 and element order 2206.

In-plane element size 2202 specifies the maximum element size for the 2-D elements in the XY plane. In one embodiment, if left to an automatic setting, the size may be determined by smallest edge size (including perforations). If the user specifies a value, that value determines the maximum element size for the extruded seed mesh. The number of elements in Z parameter 2204 specifies the number of elements in the Z direction.

The element order parameter 2206 specifies the element order. In one embodiment, the linear element order has two nodes along each edge, creating an 8-node hexahedra. This element order is specialized for mechanics. The linear element order may be enhanced with incompatible modes. In addition to the standard displacement degrees of freedom, incompatible modes include internal degrees of freedom, enabling them to represent almost all linear strain patterns. The primary effect of these degrees of freedom is to eliminate so-called parasitic shear stresses (artificial shear strains that result from numerical formulation of the elements) that are observed in standard displacement elements if they are loaded in bending. These internal degrees of freedom also eliminate artificial stiffening due to the Poisson's effect in bending. In standard displacement elements, the linear variation of the axial stress resulting from bending is accompanied by a linear variation of the stress perpendicular to the bending direction, which leads to incorrect stresses and an overestimation of the stiffness. Incompatible modes prevent such stresses from occurring.

Parabolic element order has three nodes along each mesh edge, a node at the center of each mesh face, and a node at the element center, creating 27-node hexahedra. This element order is efficient (accurate results with relatively fewer elements) and most appropriate for torsion.

In an embodiment, element order 2206 is set to linear by default and may be used or most plate applications. For example, proof masses and other large aspect ratio structures that are most appropriately modeled by plate components are frequently geometrically complex and include perforations. Since geometric complexity necessarily yields relatively dense discretization, the linear element order commonly creates a sufficiently dense mesh for simulation.

In one embodiment face type parameters for the specified component that is being meshed determines the boundary condition that is applied to a given face. Exemplary face types may include external, internal, fixed, symmetry about the XZ-plane and symmetry about the YZ-plane. External face type parameters assume the component face is exposed and is not connected to another component. An internal face type may assume that the component face is connected to another component and unexposed. Internal edges are always vertical and are not affected by sidewall angle settings in the process file. In one embodiment, an internal face type can only be assigned by the 3D design environment, and once assigned, becomes a read-only property. A fixed face type parameter may assume a fixed boundary condition on the given face. Like internal edges, fixed edges may always be vertical and not affected by sidewall angle settings in the process file. Symmetry about the XZ-plane defines a device symmetry plane in Y while symmetry about the YZ-plane defines a device symmetry plane in X. In an embodiment, the face types can be set automatically by the 3D design environment. The 3D design environment may also decide whether an edge is external, and may assign an internal face type.

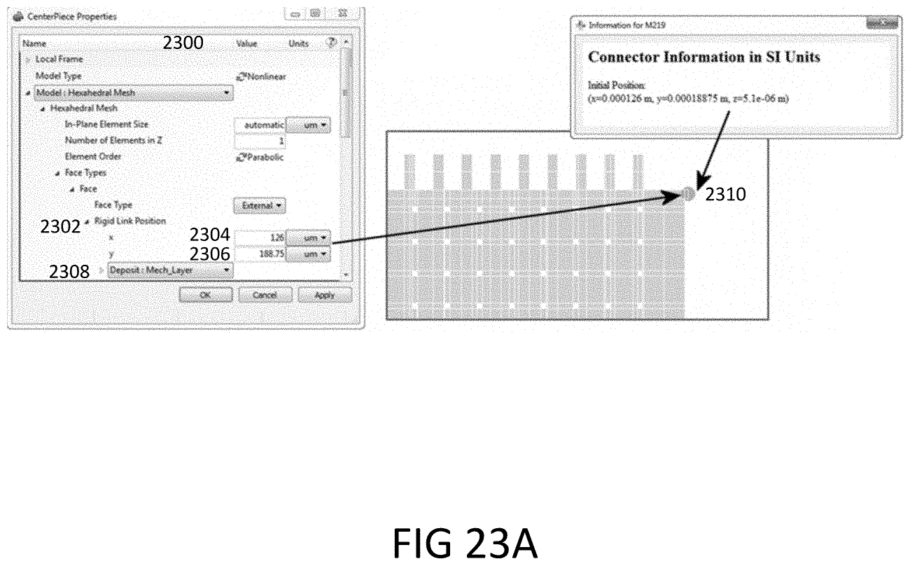

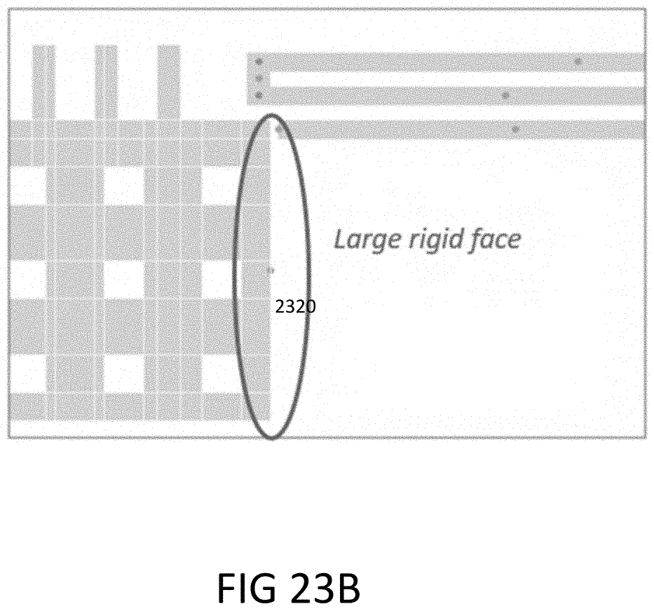

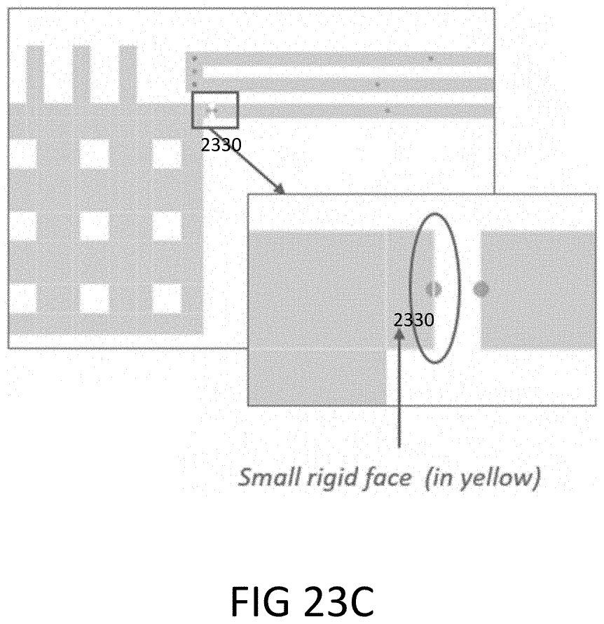

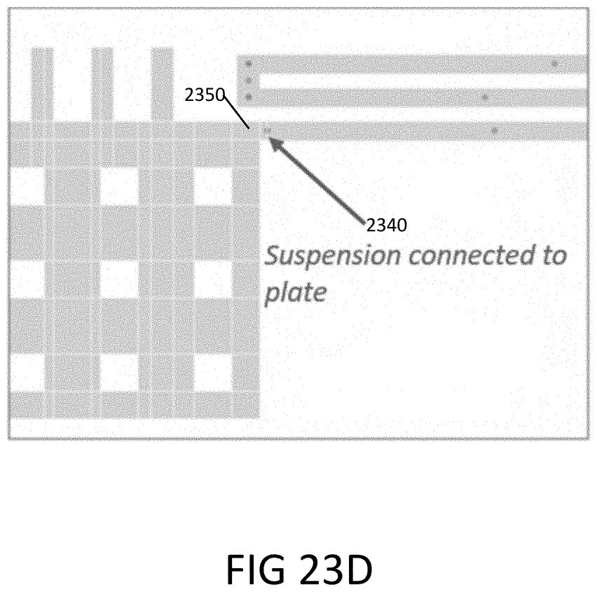

An additional parameter related to the specified component that is to be meshed is the face types/rigid link position parameter. This parameter sets the rigid link position of the created mechanical connector, which is necessary to constrain the plate and connect it to other adjacent components. FIG. 23A depicts an exemplary graphical user interface 2300 for specifying a rigid link position 2302 in an exemplary embodiment. The user enters the x 2304 and y 2306 positions of the mechanical connector in the graphical user interface 2300 and defines the z 2308 position by selecting a deposit. The closest plate face is made rigid and is assigned six DOFs (three translation and three rotation). A mechanical connector 2310 is created at the rigid link position by adding a face. The mechanical connector can be used to connect the plate to other components. In one embodiment, to add another face\rigid position link, a user may right click on the face types label, and select add element from the resulting menu. It should be noted that when a rigid link position is designated on a face, the entire face becomes rigid. Accordingly, the face size may be made as small as possible to minimize the effect of the rigid link. For example, FIG. 23B depicts a view of a large rigid face 2320, FIG. 23C depicts a view of a small rigid face 2330 in an exemplary embodiment, and FIG. 23D depicts a suspension 2340 connected to a plate component 2350 in an exemplary embodiment.

In an embodiment, for the deposit layer, the 3D design environment may allow the user to override certain parameters. For example, selection of a thickness override parameter overrides a thickness defined for the deposit in the process file. A vertical offset parameter may be provided to offset the deposit layer in a vertical direction. The offset may be applied to the bottom plane of the bottom-most layer, but all the layers may be moved accordingly. Similarly, a deposit plane selection selects the z location for the rigid link position. By default, the z location is placed in the middle of the deposit layer, but it can be moved to the top or bottom of the deposit layer.

The meshed plate may be incorporated into a schematic through the face(s) added to the plate component. The face\rigid link position property for the specified component that is to be meshed defines a mechanical connector by coordinates, which is then attached to the nearest face. The mechanical connector can be used to connect the meshed plate to other components or to apply boundary conditions. At least one face must be created to constrain the plate; but the user can add as many faces as needed. The face that has the created mechanical connector is rigid, so minimizing the rigid face size greatly reduces the impact of rigid links. Rather than attach a mechanical connector to a large face, a trivial face may be created and the mechanical connector attached to that face. The face\rigid link position may be used to create a mechanical connector at each point of attachment. In one embodiment, scripting can be used to automatically create mechanical connectors at the required positions.

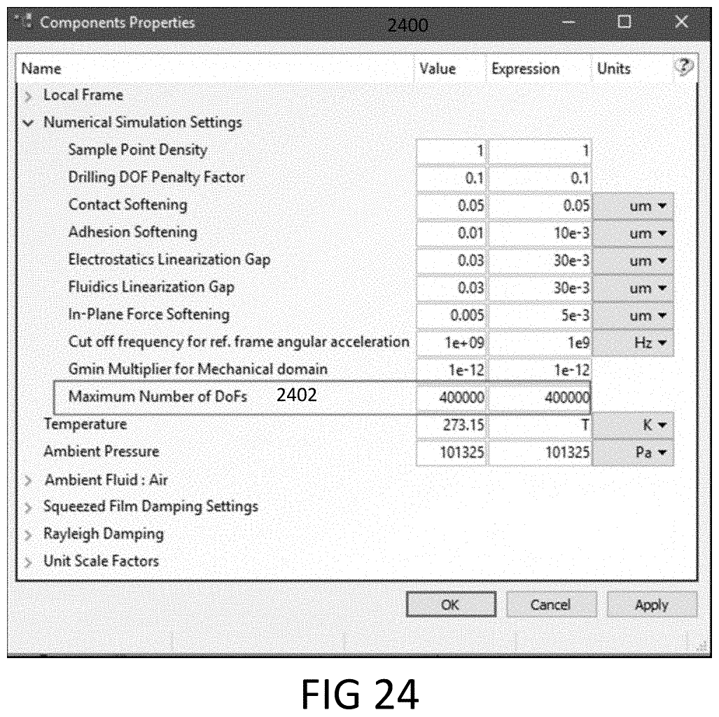

The hexahedral mesh model allows for a user to generate large schematics in terms of the number of degrees of freedom. Simulation time is primarily dictated by the number of degrees of freedom. Memory (RAM) is the most critical system resource as more memory allows the simulation of larger systems. If all the physical memory of the system is consumed, memory content is swapped to the hard disk. In such a situation, the simulation time is highly affected, and simulation might not converge. Accordingly, in one embodiment, the maximum number of degrees of freedom allowed for a simulation to be conducted by the 3D design environment is currently limited to −3 million. Users can elect to decrease the maximum allowed number of degrees of freedom (DoF) in a component properties dialog provided by the 3D design environment. FIG. 24 depicts an exemplary graphical user interface 2400 provided by the 3D design environment enabling a user to specify a maximum number of degrees of freedom 2402 in a simulation using a meshed component. In one embodiment, if a model exceeds the maximum number of DoF, the simulator will issue an error message when attempting to run an analysis.

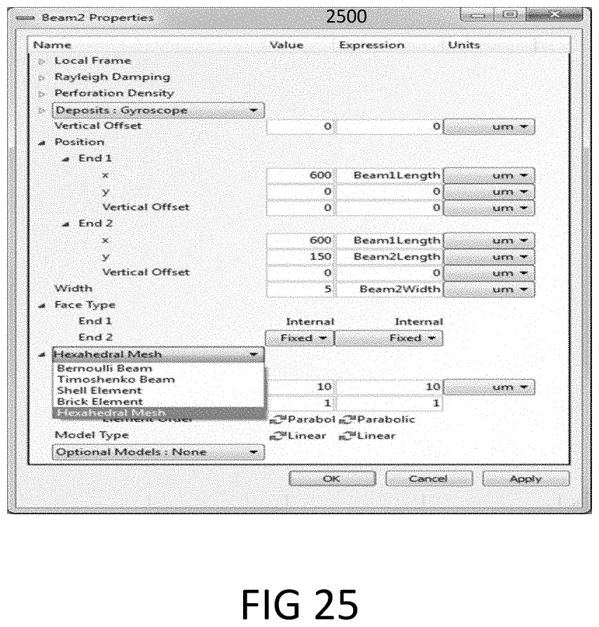

In one embodiment, beam and suspension components can also be meshed in the 3D design environment using hexahedral elements in response to a user selecting a hexahedral mesh option from a drop down or other menu provided in a graphical user interface in the 3D design environment. FIG. 25 depicts a graphical user interface 2500 provided by the 3D design environment configured to accept hexahedral meshing parameters for a beam in an exemplary embodiment. In one embodiment, meshed beam components do not support child components (Gaps or Stacks). To create the mesh, the mesh generator of the 3D design environment relies on two input parameters: in-plane element size parameter and the number of elements in Z parameter. The in-plane element size parameter defines the target value for the edge length of an element in plane. This value may only be an indication of the desired size; depending on the geometry being meshed, the edge length of an actual element will likely not exactly match the target value. In one embodiment, the default value for this setting is automatic. The definition of automatic depends on the geometry of the device, which in turn, determines the type of mesher used on the suspension. As mentioned above, there are multiple meshing options in the 3D design environment. If the orthogonal mesher is used, the default in-plane size value of automatic will generate the largest elements that preserve the orthogonality of the mesh. In contrast, if the geometry is incompatible with the orthogonal mesher (e.g.: due to multiple layers, large sidewall angle, curved shapes, etc.), one of the extruded meshers described above may be used.

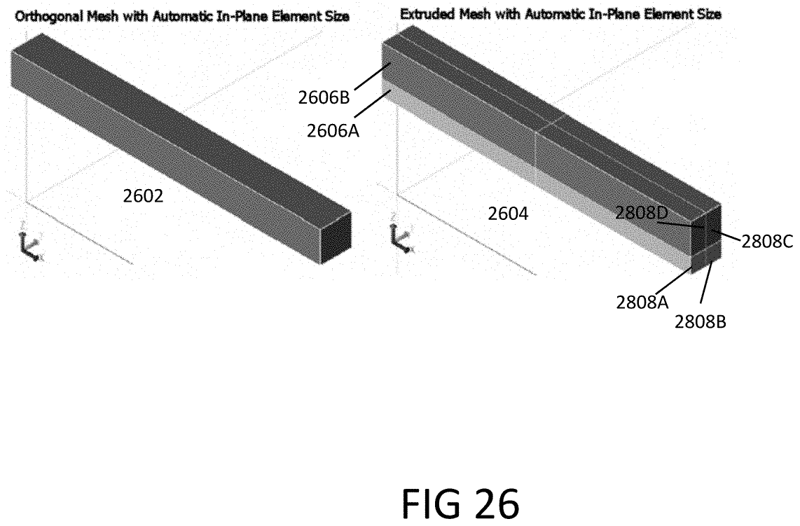

For extruded meshes, the automatic setting means that there will be at least four elements in plane. FIG. 26 depicts a view of differences between an orthogonal mesh and an extruded mesh in an exemplary embodiment. Compare the beam on the left 2602 with the beam on the right 2604. Because the beam on the left 2602 only has one layer, it is meshed with the orthogonal (“Manhattan Bricks”) mesher, and the automatic value creates one element in plane. Since the beam on the right 2604 has two layers 2606A and 2606B, an extruded mesher is used, and four elements 2808A, 2808B, 2808C and 2808D are created in plane.

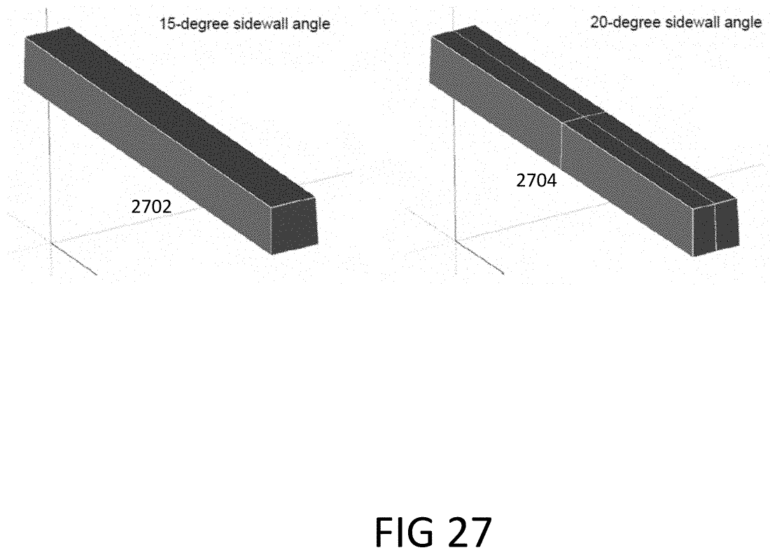

FIG. 27 depicts a view of the effect of sidewall angle in an orthogonal mesh and an extruded mesh in an exemplary embodiment. With a 15-degree sidewall angle, the orthogonal mesher can be used, so the result is one element in plane as depicted by beam 2702. However, with the 20-degree sidewall angle, the geometry is no longer supported by the orthogonal mesher, so the extruded mesher is used, and the result is four elements in plane as depicted by beam 2704.

The number of elements in Z parameter specifies the number of elements in the Z direction for each layer. If the suspension is comprised of one layer, this value specifies the number of elements through the entire suspension thickness. If the suspension is comprised of multiple layers, each layer will be discretized to include this number of elements through its thickness. If the number of elements in Z parameter is set to one, a single-layer beam will only have one element through the thickness. However, for a two-layer beam, there is one element through the thickness of each layer.

The element order parameter sets the order of the mesh elements. The linear element order has two nodes along each edge, creating 8-node hexahedra. This element order is specialized for mechanics and may be used for large parts that have little deformation. In one embodiment, the linear element order is enhanced with incompatible modes. In addition to the standard displacement degrees of freedom, these incompatible modes have internal degrees of freedom, enabling them to represent almost all linear strain patterns. The primary effect of these degrees of freedom is to eliminate the so-called parasitic shear stresses (artificial shear strains that result from numerical formulation of the elements) that are observed in standard displacement elements if they are loaded in bending. These internal degrees of freedom also eliminate artificial stiffening due to Poisson's effect in bending. In standard displacement elements, the linear variation of the axial stress resulting from bending is accompanied by a linear variation of the stress perpendicular to the bending direction, which leads to incorrect stresses and an overestimation of the stiffness. The incompatible modes prevent such a stress from occurring.

The parabolic element order has three nodes along each mesh edge, a node at the center of each mesh face, and a node at the element center, creating 27-node hexahedra (or bricks). Parabolic elements are also referred to as quadratic elements. This element order may be used for parts where deformation is at a maximum.

Meshed suspension components, similar to Bernoulli beams, only have two mechanical connectors, one on each end of the suspension. The entire face of each end of the meshed suspension is connected to its respective mechanical connector. As a result, the two end faces of the meshed model are rigid. The connection between meshed suspensions and other components will therefore be strictly identical to the connection between Bernoulli suspensions and other components.

Meshed suspensions allow users to analyze complex beam and suspension components in their MEMS devices for which compact FEA components are not suitable. Hexahedral meshing may be useful under different circumstances. For example, hexahedral meshing can be used to verify modal frequencies of complex suspensions. Additionally, in the case of short, stubby beams, a hexahedral mesh is preferred. Also, if the sidewall angle is greater than 2 degrees, a hexahedral mesh is preferred. Further, because the inherent assumption in the Bernoulli beam is that the cross-section of the beam is assumed to be planar to the deformed axis, a meshed suspension may be preferred in cases of beams and suspensions undergoing torsion. It should be appreciated however that there are some situations where hexahedral meshing may not be optimal. For example, if a model requires multiple separate meshed components in which their faces meet, these facial connections are treated as rigid faces. As a result, the model will exhibit artificially excessive stiffness. For the plate component, this can be overcome using the Face\Rigid Link Position property. Additionally, in problems with more than 3 million of degrees of freedom meshing may not be suitable because the solver cannot factorize a matrix of that size. If the mesh results in high DOF, a user may save time by generating a ROM for further analysis. Further hexahedral meshing may not be supported when the component has a child component, such as an Inherited Gap or Inherited Stack.

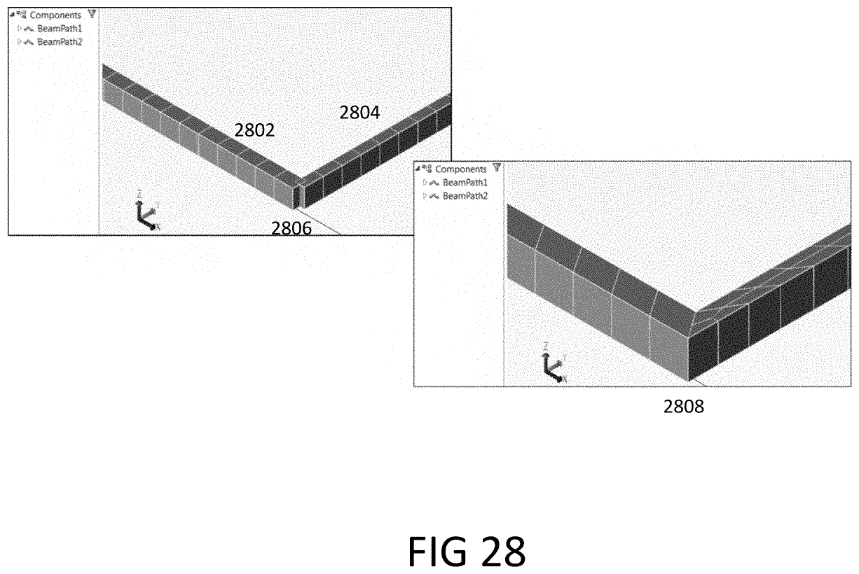

If multiple Beam components or a Beam and a Plate intersect and their mechanical connectors are coincident, the 3D design environment merges the geometry of those components such that there are no gaps between the components. If the Beam components are modeled with hexahedral mesh elements, the 3D design environment may create a non-conformal mesh at the interface between the two beams. For example, FIG. 28 depicts a view of meshing with merged geometry in an exemplary embodiment. The interface 2806 between beams 2802 and 2804 is merged 2808. This non-conformal mesh will not cause difficulty for the simulator solvers because the end faces of any meshed beam are considered rigid (meaning that all the nodes of an end face are tied to the central mechanical connector).

It is important not to overmesh a component as the elements are of order 2 and already quite accurate. Creating an overly refined mesh with a substantial number of degrees of freedom is therefore not recommended because the solver cannot factorize an excessively large matrix. Instead, a convergence study should be run on the user's suspension starting with a coarse mesh, and progressively refining to achieve a converged result.

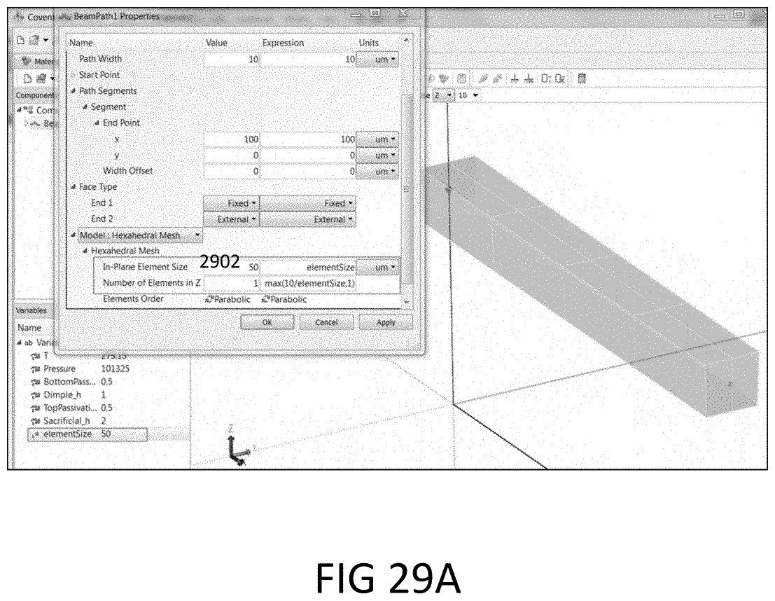

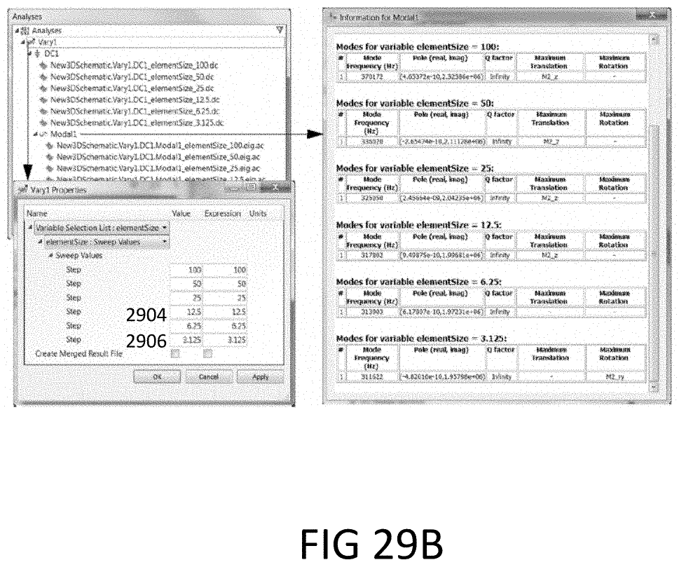

In one embodiment the 3D design environment enables a convergence study to be run. FIGS. 29A-29B depict graphical user interfaces for user selection of parameters for running a convergence study in an exemplary embodiment. To run the study a user first uses a variable to define the in-plane element size parameter 2902 and expose it. For the number of elements in Z parameter, the user divides the thickness of the plate by the desired element size and forces a minimum value of 1. This variable is systematically varied and a modal is run for each value. The 3D design environment may provide modal analysis reports indicating the mode frequency for each element size. As depicted in FIG. 29B, by reducing the element size 2904 from 100 to 12.5, the first mode shifts by 52 kHz; however, further reducing the element size 2906 from 12.5 to 3.125, the first mode frequency shifts by 6 kHz, indicating that the solution is converging.

The present invention may be provided as one or more computer-readable programs embodied on or in one or more computer-readable mediums. The mediums may be a floppy disk, a hard disk, a compact disc, a digital versatile disc, a flash memory card, a PROM, a RAM, a ROM, or a magnetic tape. In general, the computer-readable programs may be implemented in any programming language. The software programs may be stored on or in one or more mediums as object code. The code may run in a virtualized environment such as in a virtual machine. Multiple virtual machines running the code may be resident on a single processor.

Since certain changes may be made without departing from the scope of the present invention, it is intended that all matter contained in the above description or shown in the accompanying drawings be interpreted as illustrative and not in a literal sense. Practitioners of the art will realize that the sequence of steps and architectures depicted in the figures may be altered without departing from the scope of the present invention and that the illustrations contained herein are singular examples of a multitude of possible depictions of the present invention.

We claim:

1. A computing device-implemented method of creating 3D MEMS device models from 2D polygonal descriptions in a 3D design environment, comprising:
providing a parameterized component library holding a plurality of components for the 3D design environment, the plurality of components each having a geometric shape;
receiving in the 3D design environment a user configuration of each component of the plurality of components, the user configuration specifying a layer of a 2D polygonal description on which the component is expected to appear;
importing a 2D polygonal description of a MEMS device model into the 3D design environment, the 2D polygonal description including a plurality of geometric shapes and a plurality of layers and separating model functionality by layer;
identifying in the 3D design environment each geometric shape on each layer of the imported 2D polygonal description;
identifying in the 3D design environment a corresponding component from the plurality of components in the parameterized component library for each of the geometric shapes identified on a layer; and
assembling in the 3D design environment a plurality of heterogeneous components into a 3D MEMS device model using a plurality of corresponding components.

2. The method of claim 1, further comprising:
receiving in the 3D design environment a user configuration of a model parameter for at least one specified component in the component library, the user configuration designating the model parameter for the specified component as a hexahedral mesh;
meshing the at least one specified component with a hexahedral mesh; and
including the at least one specified component in the 3D MEMS device model.

3. The method of claim 2, further comprising:
receiving in the 3D design environment a user configuration adding at least one face to the specified component; and
adding a mechanical connector to the added at least one face that establishes a connection to an adjacent component.

4. The method of claim 2, wherein a type of the hexahedral meshing is automatically selected by the 3D design environment based upon a geometry exhibited by the at least one specified component.

5. The method of claim 2 wherein the at least one specified component is a plate component or a beam component.

6. The method of claim 2, further comprising:
receiving in the 3D design environment a user specification of a maximum number of degrees of freedom allowed in a simulation including the at least one specified component.

7. The method of claim 1, further comprising:
identifying in the 3D design environment a corresponding component from the plurality of components in the parameterized component library for a pattern of geometric shapes identified on a layer.

8. The method of claim 1 wherein the plurality of heterogeneous components have a hierarchical relationship.

9. The method of claim 1, further comprising:
creating a 2D polygonal description from the 3D MEMS device model.

10. The method of claim 9, wherein the creating:
identifies a component in the 3D MEMS device model;
identifies a corresponding component in the parameterized component library; and
inserts data related to the component on a layer of the 2D polygonal description specified in a configuration of the corresponding component in the component library.

11. A non-transitory medium holding computing device-executable instructions for creating 3D MEMS device models from 2D polygonal descriptions in a 3D design environment, the instructions when executed causing at least one computing device to:
provide a parameterized component library holding a plurality of components for the 3D design environment, the plurality of components each having a geometric shape;
receive in the 3D design environment a user configuration of each component of the plurality of components, the user configuration specifying a layer of a 2D polygonal description on which the component is expected to appear;
import a 2D polygonal description of a MEMS device model into the 3D design environment, the 2D polygonal description including a plurality of geometric shapes and a plurality of layers and separating model functionality by layer;
identify in the 3D design environment each geometric shape on each layer of the imported 2D polygonal description;
identify in the 3D design environment a corresponding component from the plurality of components in the parameterized component library for each of the geometric shapes; and
assemble in the 3D design environment a plurality of heterogeneous components into a 3D MEMS device model using a plurality of corresponding components.

12. The medium of claim 11, wherein the instructions when executed further cause the at least one computing device to:
receive in the 3D design environment a user configuration of a model parameter for at least one specified component in the component library, the user configuration designating the model parameter for the specified component as a hexahedral mesh;
mesh the at least one specified component with a hexahedral mesh; and
include the at least one specified component in the 3D MEMS device model.

13. The medium of claim 12, wherein the instructions when executed further cause the at least one computing device to:
receive in the 3D design environment a user configuration adding at least one face to the specified component; and
add a mechanical connector to the added at least one face that establishes a connection to an adjacent component.

14. The medium of claim 12, wherein a type of the hexahedral meshing is automatically selected by the 3D design environment based upon a geometry exhibited by the at least one specified component.

15. The medium of claim 12 wherein the at least one specified component is a plate component or a beam component.

16. The medium of claim 12, wherein the instructions when executed further cause the at least one computing device to:
receive in the 3D design environment a user specification of a maximum number of degrees of freedom allowed in a simulation including the at least one specified component.

17. The medium of claim 11 wherein the instructions when executed further cause the at least one computing device to:
identify in the 3D design environment a corresponding component from the plurality of components in the parameterized component library for a pattern of geometric shapes identified on a layer.

18. The medium of claim 11 wherein the plurality of heterogeneous components have a hierarchical relationship.

19. The medium of claim 11, wherein the instructions when executed further cause the at least one computing device to:
create a 2D polygonal description from the 3D compact MEMS device model.

20. The medium of claim 19, wherein the creating:
identifies a component in the 3D compact MEMS device model;
identifies a corresponding component in the parameterized component library; and
inserts data related to the component on a layer of the 2D polygonal description specified in a configuration of the corresponding component in the component library.

21. A system for creating 3D MEMS device models from 2D polygonal descriptions in a 3D design environment, comprising:
at least one computing device equipped with a processor and configured to generate a 3D design environment for MEMS device models, the 3D design environment configured to:
provide a parameterized component library holding a plurality of components for the 3D design environment, the plurality of components each having a geometric shape,
receive a user configuration of each component of the plurality of components, the user configuration specifying a layer of a 2D polygonal description on which the component is expected to appear,
import a 2D polygonal description of a MEMS device model, the 2D polygonal description including a plurality of geometric shapes and a plurality of layers and separating model functionality by layer,
identify each geometric shape on each layer of the imported 2D polygonal description,
identify a corresponding component from the plurality of components in the parameterized component library for each of the geometric shapes, and
assemble a plurality of heterogeneous components into a 3D MEMS device model using a plurality of corresponding components; and
a display surface in communication with the computing device, the display surface configured to display the 3D MEMS device model in a 3D view.

22. The system of claim 21, wherein the 3D design environment is further configured to:
receive in the 3D design environment a user configuration of a model parameter for at least one specified component in the component library, the user configuration designating the model parameter for the specified component as a hexahedral mesh;
mesh the at least one specified component with a hexahedral mesh; and
include the at least one specified component in the 3D MEMS device model.

23. The system of claim 21, wherein the 3D design environment is further configured to:
identify a corresponding component from the plurality of components in the parameterized component library for a pattern of geometric shapes identified on a layer.
